(19) United States
(12) Patent Application Publication
(10) Pub. No.: US 2026/0229158 A1
(43) Pub. Date: Aug. 6, 2026

(54) DISPLAY PANEL AND DRIVING METHOD THEREOF, AND DISPLAY DEVICE

(71) Applicant: Wuhan Tianma Micro-Electronics Co., Ltd., Wuhan (CN)

(72) Inventors: Hao DAI, Wuhan (CN); Ruiheng RAO, Wuhan (CN); Zhongye YI, Wuhan (CN)

(21) Appl. No.: 19/426,456

(22) Filed: Dec. 19, 2025

(30) Foreign Application Priority Data
Feb. 6, 2025 (CN) 202510134169.4

(51) Int. Cl. G09G 3/20; G09G 3/3233; H10K 59/123; H10K 59/35

(52) U.S. Cl. CPC G09G 3/2007; G09G 3/3233; H10K 59/123; H10K 59/353; G09G 2300/0452; G09G 2320/0209; G09G 2320/0233; G09G 2320/0242; G09G 2320/045; G09G 2320/066

(57) ABSTRACT

A display panel and its driving method, and a display device are provided. The display panel includes a base substrate and light-emitting devices. The light-emitting devices include first light-emitting devices and second light-emitting devices. One first light-emitting device includes a first anode portion and a first cathode portion that are arranged opposite to each other, and a first light-emitting layer located between the first anode portion and the first cathode portion. One second light-emitting device includes a second anode portion and a second cathode portion that are arranged opposite to each other, and at least two second light-emitting layers located between the second anode portion and the second cathode portion. A connecting layer is disposed between two adjacent layers of the at least two second light-emitting layers and a light-emitting color of each of the at least two second light-emitting layers is same in the same second light-emitting device.

### CROSS-REFERENCE TO RELATED APPLICATION

This application claims the priority of Chinese Patent Application No. 202510134169.4, filed on February 6, 2025, the content of which is incorporated herein by reference in its entirety.

### TECHNICAL FIELD

The present disclosure generally relates to the field of display technology and, more particularly, relates to a display panel and its driving method, and a display device.

### BACKGROUND

Organic Light-Emitting Diodes (OLEDs) are a new generation of display technology that is popular and has great development prospects in recent years. The OLEDs have advantages of self-luminescence, ultra-light and thin, a wide viewing angle, a fast response speed, high luminous efficiency and brightness, a wide operating temperature range, a simple production process, low power consumption, and flexibility. The OLEDs are currently widely used in many fields such as flat panel display, flexible display, vehicle display and solid-state lighting.

A Tandem OLED device is a stacked OLED device formed by electrically connecting multiple organic light-emitting units in series inside the device. The Tandem OLED device has characteristics of high efficiency and long life.

However, because of the improved efficiency of Tandem OLED device, the current required at the same brightness is significantly reduced. In particular, for low-brightness and low-grayscale images, the difference caused by the change in the characteristics of thin-film transistors will be magnified because of the decrease in current, and the local uniformity and contrast uniformity will deteriorate when displaying low grayscale. Also, because of the serious lateral leakage of The Tandem OLED device and the serious crosstalk of low grayscale leakage, the color gamut and overall display effect of low grayscale will be affected, resulting in poor low grayscale display effect.

### SUMMARY

One aspect of the present disclosure provides a display panel. The display panel includes a base substrate and light-emitting devices. The light-emitting devices include first light-emitting devices and second light-emitting devices. One first light-emitting device includes a first anode portion and a first cathode portion that are arranged opposite to each other, and a first light-emitting layer located between the first anode portion and the first cathode portion. One second light-emitting device includes a second anode portion and a second cathode portion that are arranged opposite to each other, and at least two second light-emitting layers located between the second anode portion and the second cathode portion. A connecting layer is disposed between two adjacent layers of the at least two second light-emitting layers and a light-emitting color of each of the at least two second light-emitting layers is same in the same second light-emitting device.

Another aspect of the present disclosure provides a driving method of a display panel. The display panel includes a base substrate and light-emitting devices. The light-emitting devices include first light-emitting devices and second light-emitting devices. One first light-emitting device includes a first anode portion and a first cathode portion that are arranged opposite to each other, and a first light-emitting layer located between the first anode portion and the first cathode portion. One second light-emitting device includes a second anode portion and a second cathode portion that are arranged opposite to each other, and at least two second light-emitting layers located between the second anode portion and the second cathode portion. A connecting layer is disposed between two adjacent layers of the at least two second light-emitting layers and a light-emitting color of each of the at least two second light-emitting layers is same in the same second light-emitting device. The method includes that, in a first mode, a brightness of the display panel is L1, the first light-emitting devices emit light, and the second light-emitting devices do not emit light; and, in a second mode, the brightness of the display panel is L2, the second light-emitting devices emit light, or the first light-emitting devices and the second light-emitting devices emit light at the same time.

Another aspect of the present disclosure provides a display device including a display panel. The display panel includes a base substrate and light-emitting devices. The light-emitting devices include first light-emitting devices and second light-emitting devices. One first light-emitting device includes a first anode portion and a first cathode portion that are arranged opposite to each other, and a first light-emitting layer located between the first anode portion and the first cathode portion. One second light-emitting device includes a second anode portion and a second cathode portion that are arranged opposite to each other, and at least two second light-emitting layers located between the second anode portion and the second cathode portion. A connecting layer is disposed between two adjacent layers of the at least two second light-emitting layers and a light-emitting color of each of the at least two second light-emitting layers is same in the same second light-emitting device.

Other aspects or embodiments of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates an exemplary display panel consistent with various disclosed embodiments in the present disclosure.

FIG. 2 illustrates a cross-sectional view of the display device along an A-A’ direction in FIG. 1 consistent with various disclosed embodiments in the present disclosure.

FIG. 3 illustrates another exemplary display panel consistent with various disclosed embodiments in the present disclosure.

FIG. 4 illustrates another cross-sectional view of the display device along an A-A’ direction in FIG. 1 consistent with various disclosed embodiments in the present disclosure.

FIG. 5 illustrates another exemplary display panel consistent with various disclosed embodiments in the present disclosure.

FIG. 6 illustrates another exemplary display panel consistent with various disclosed embodiments in the present disclosure.

FIG. 7 illustrates another exemplary display panel consistent with various disclosed embodiments in the present disclosure.

FIG. 8 illustrates another exemplary display panel consistent with various disclosed embodiments in the present disclosure.

FIG. 9 illustrates another exemplary display panel consistent with various disclosed embodiments in the present disclosure.

FIG. 10 illustrates another exemplary display panel consistent with various disclosed embodiments in the present disclosure.

FIG. 11 illustrates another exemplary display panel consistent with various disclosed embodiments in the present disclosure.

FIG. 12 illustrates another exemplary display panel consistent with various disclosed embodiments in the present disclosure.

FIG. 13 illustrates a cross-sectional view of the display device along a B-B’ direction in FIG. 12 consistent with various disclosed embodiments in the present disclosure.

FIG. 14 illustrates another cross-sectional view of the display device along a B-B’ direction in FIG. 12 consistent with various disclosed embodiments in the present disclosure.

FIG. 15 illustrates another exemplary display panel consistent with various disclosed embodiments in the present disclosure.

FIG. 16 illustrates a positional relationship between a second light-emitting device and an isolation component consistent with various disclosed embodiments in the present disclosure.

FIG. 17 illustrates another exemplary display panel consistent with various disclosed embodiments in the present disclosure.

FIG. 18 illustrates a top view of a driving transistor in a first pixel circuit and a driving transistor in a second pixel circuit of a display panel consistent with various disclosed embodiments in the present disclosure.

FIG. 19 illustrates an exemplary display device consistent with various disclosed embodiments in the present disclosure.

### DETAILED DESCRIPTION

Reference will now be made in detail to exemplary embodiments of the disclosure, which are illustrated in the accompanying drawings. Hereinafter, embodiments consistent with the disclosure will be described with reference to drawings. In the drawings, the shape and size may be exaggerated, distorted, or simplified for clarity. Wherever possible, the same reference numbers will be used throughout the drawings to refer to the same or like parts, and a detailed description thereof may be omitted. Further, in the present disclosure, the disclosed embodiments and the features of the disclosed embodiments may be combined under conditions without conflicts. It is apparent that the embodiments described are some but not all of the embodiments of the present disclosure. Based on the disclosed embodiments, those ordinarily skilled in the art may derive other embodiments consistent with the present disclosure, all of which are within the scope of the present disclosure.

Moreover, the present disclosure is described with reference to schematic diagrams. For the convenience of descriptions of the embodiments, the cross-sectional views illustrating the device structures may not follow the common proportion and may be partially exaggerated. Besides, those schematic diagrams are merely examples, and not intended to limit the scope of the disclosure. Furthermore, a three-dimensional (3D) size including length, width, and depth should be considered during practical fabrication.

In the present disclosure, terms such as “center”, “longitudinal”, “lateral”, “length”, “width”, “thickness”, “up”, “down”, “front”, “back”, “left”, “right”, “vertical”, “horizontal”, “top”, “bottom”, “inside”, “outside”, “clockwise”, “counterclockwise”, “axial”, “radial”, “circumferential”, etc., indicate orientations or positional relationships based on the orientations or positional relationships shown in the accompanying drawings, and are only for the convenience of describing the present disclosure and simplifying the description, and do not indicate or imply that the device or element referred to must have a specific orientation, be constructed and operated in a specific orientation, and therefore should not be understood as limiting the present disclosure.

In the present disclosure, relational terms such as first and second are only used to distinguish one entity or operation from another entity or operation, and do not necessarily require or imply any actual relationship between these entities or operations or order. Moreover, the terms “including”, “comprising” or any other variants thereof are intended to cover non-exclusive inclusion, such that a process, method, article, or device that includes a series of elements includes not only those elements, but also those that are not explicitly listed or also include elements inherent to this process, method, article or equipment. If there are no more restrictions, the elements defined by the sentence “including...” do not exclude the existence of other same elements in the process, method, article, or equipment that includes the elements.

It should be understood that when describing the structure of a component, when a layer or region is referred to as being “on” or “above” another layer or another region, the layer or region may be directly on the other layer or region, or indirectly on the other layer or region, for example, layers/components between the layer or region and another layer or another region. And, for example, when the component is reversed, the layer or region may be “below” or “under” the other layer or region. In the present disclosure, the term “electrical connection” refers to that two components are directly electrically connected with each other, or the two components are electrically connected via one or more other components.

In the present disclosure, unless otherwise clearly specified and limited, the terms “installed”, “connected”, “fixed” and the like appear, should be understood in a broad sense. For example, it can be a fixed connection, a detachable connection, or an integrated connection; it can be a mechanical connection or an electrical connection; it can be a direct connection or an indirect connection through an intermediate medium, it can be the internal connection of two elements or the interaction relationship between two elements, unless otherwise clearly defined. For those skilled in the art, the specific meanings of the above terms in the present disclosure can be understood according to the specific circumstances.

In the present disclosure, when an element is referred to as being “fixed to” or “disposed on” another element, it may be directly on the other element or there may be an intermediate element. When an element is considered to be “connected to” another element, it may be directly connected to the other element or there may be an intermediate element at the same time. If present, the terms “vertical”, “horizontal”, “upper”, “lower”, “left”, “right” and similar expressions are for illustrative purposes only and are not intended to be the only embodiment.

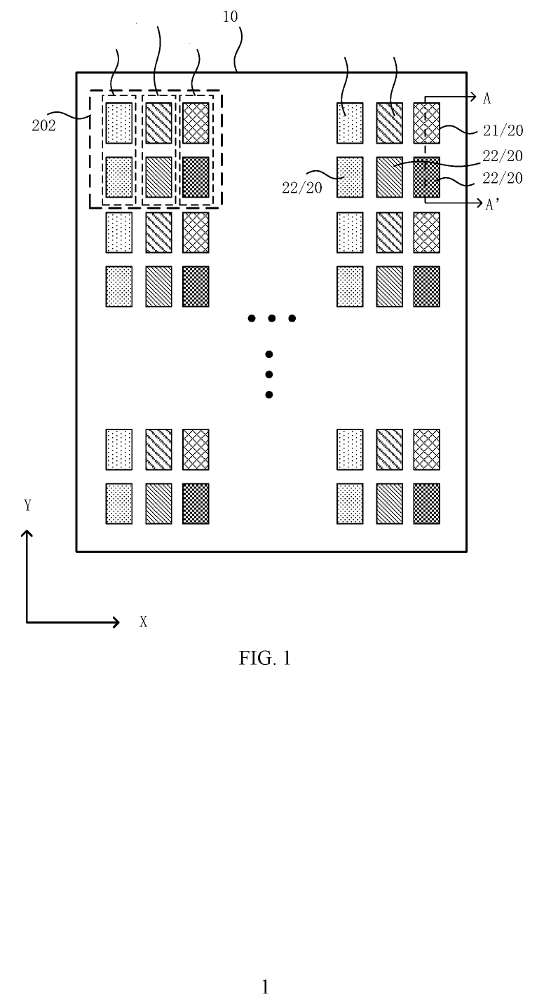

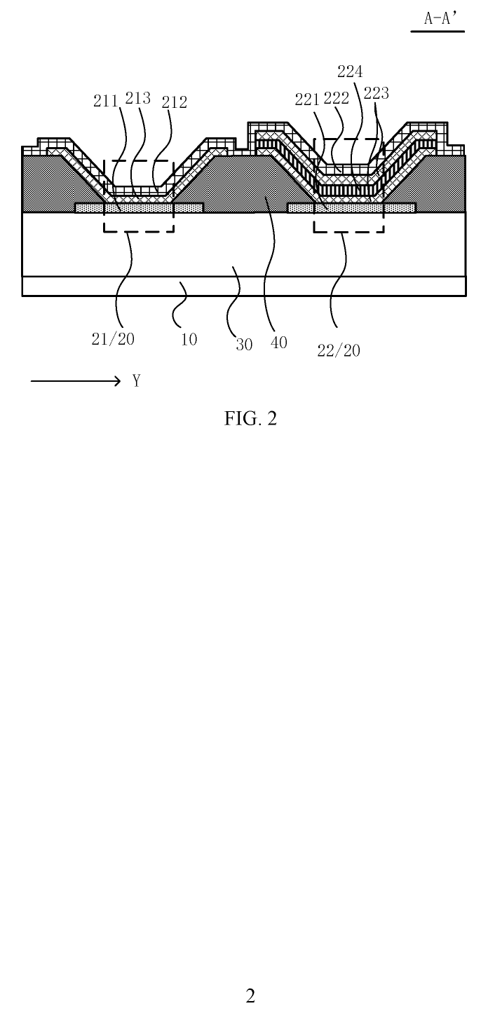

The present disclosure provides a display panel. In one embodiment, as shown in FIG. 1 which illustrates an exemplary display panel and FIG. 2 which illustrates a cross-sectional view of the display panel in FIG. 1 along an A-A’ direction, the display panel may include a base substrate 10 and a plurality of light-emitting devices 20 disposed on a side of the base substrate 10.

The plurality of light-emitting devices 20may include first light-emitting devices 21 and second light-emitting devices 22.

One first light-emitting device 21 may include: a first anode portion 211 and a first cathode portion 212 arranged opposite to each other, and a first light-emitting layer 213 located between the first anode portion 211 and the first cathode portion 212.

One second light-emitting device 22 may include a second anode portion 221 and a second cathode portion 222 arranged opposite to each other, and at least two second light-emitting layers 223 located between the second anode portion 221 and the second cathode portion 222. A connecting layer 224 may be disposed between two adjacent second light-emitting layers 223. In one same second light-emitting device 22, the light-emitting colors of each second light-emitting layer 223 may be the same.

The display panel may include the base substrate 10. In one embodiment, the base substrate may be a rigid base substrate, and the material of the base substrate 10 may be glass. The base substrate 10 may also be a flexible base substrate in some other embodiments, and the material of the base substrate 10 may be polyimide (PI), polycarbonate (PC) or polyethylene terephthalate (PET), etc. The base substrate 10 may be used to support and protect film layers formed thereon.

Optionally, the display panel may further include an array layer 30 disposed on the base substrate 10. The array layer 30 may include pixel circuits for driving the plurality of light-emitting device 20 to emit light. One pixel circuit may correspond to at least one light-emitting device 20 of the plurality of light-emitting device 20. One light-emitting device 20 may be electrically connected to one corresponding pixel circuit. Light-emitting devices 20 of the plurality of light-emitting device 20 electrically connected to one same pixel circuit may form a sub-pixel, that is, one pixel circuit and the light-emitting device 20 electrically connected to the pixel circuit together form a sub-pixel. A plurality of sub-pixels may display the picture together. It should be noted that the specific circuit structure of the pixel circuits may be set by those skilled in the art according to actual conditions. For example, it may be 2T1C (two transistors and one capacitor), 7T1C, 8T1C, or other circuits in the relevant technology, and the present disclosure does not specifically limit this.

It should be noted that FIG. 1, which exemplarily shows that the vertical projection pattern of one light-emitting device 20 on the plane where the base substrate 10 is located is a rectangle is used as an example only to illustrate the present disclosure. In other embodiments of the present disclosure, the vertical projection pattern of one light-emitting device 20 on the plane where the base substrate 10 is located may also be other shapes, which will not be described in detail in the present disclosure.

The display panel may further include a pixel definition layer 40 disposed on a side of the array layer 30 away from the base substrate 10. The pixel definition layer 40 may be made of a material including an insulating material. The pixel definition layer 40 may include a plurality of openings. The pixel definition layer 40 may be used to define light-emitting areas through the plurality of openings. The light-emitting areas may be used to set the plurality of light-emitting devices 20.

The plurality of light-emitting devices 20 may include first light-emitting devices 21 and second light-emitting devices 22. One first light-emitting device 21 may include a first anode portion 211 and a first cathode portion 212 that are arranged opposite to each other, and a first light-emitting layer 213 located between the first anode portion 211 and the first cathode portion 212, that is, the first light-emitting device 21 may be a single-layer light-emitting device.

One second light-emitting device 22 may include a second anode portion 221 and a second cathode portion 222 that are arranged opposite to each other, and at least two second light-emitting layers 223 located between the second anode portion 221 and the second cathode portion 222. A connecting layer 224 may be disposed between two adjacent second light-emitting layers 223. In one same second light-emitting device 22, the light-emitting colors of each second light-emitting layer 223 may be the same, that is, the second light-emitting device 22 may be a stacked light-emitting device. That is, the second light-emitting device 22 may include at least two light-emitting units connected in series, and adjacent light-emitting units may be connected via the connecting layer 224. The stacked light-emitting device may have a higher device efficiency and longer life.

FIG. 2 which exemplarily shows that the second light-emitting device 22 in the display panel includes two second light-emitting layers 223 is used as an example to illustrate the present disclosure. In other embodiments of the present disclosure, the second light-emitting device 22 may also include more than two layers of second light-emitting layers 223, which will not be described in detail in the present disclosure.

It is understandable that one light-emitting device 20 may further include a hole injection layer (HIL), a hole transport layer (HTL), a hole blocking layer (HBL), an electron blocking layer (EBL), an electron transport layer (ETL), and/or an electron injection layer (EIL), etc., which will not be described in detail in the present disclosure.

In a low grayscale display mode, a driving current that drives one second light-emitting devices 22 to emit light may become smaller. Because of the smaller driving current, the difference caused by the change in the characteristics of the thin film transistor in the pixel circuit electrically connected thereto may be amplified, such that the local uniformity and contrast uniformity of the display panel may deteriorate. Moreover, because of the serious lateral leakage of the second light-emitting device 22, in the low grayscale display mode, the leakage crosstalk may seriously affect the color gamut and the overall display effect, resulting in poor low grayscale display effect.

The display panel provided by the embodiments of the present disclosure may be provided with the first light-emitting devices 21 and the second light-emitting devices 22 together. The first light-emitting devices 21 and the second light-emitting devices 22 may be different types of light-emitting devices 20. The first light-emitting devices 21 may be single-layer light-emitting devices and the second light-emitting devices 22 may be stacked light-emitting devices, such that the light-emitting states of the two types of light-emitting devices 20 may be flexibly changed according to the application scenario or usage requirements. For example, in a scenario with high brightness requirements, the second light-emitting devices 22 may be mainly relied on for light emission. The stacked light-emitting devices usually have higher light-emitting efficiency and longer service life. In low power consumption or low grayscale display, the first light-emitting devices 21 may be used more for light emission. The single-layer light-emitting devices may perform well in low grayscale display and may provide better contrast and color reproduction. This design may support multiple display modes, and may operate in a high-efficiency mode or in a mode requiring a long life and a high low grayscale display effect, thereby taking into account high efficiency, long life and low grayscale display effects, and meeting the needs of different users and applications.

Optionally, the display panel may have a first mode and a second mode. In the first mode, the brightness of the display panel may be L1, the first light-emitting devices 21 may emit light, and the second light-emitting devices 22 may not emit light. In the second mode, the brightness of the display panel may be L2, and the second light-emitting devices 22 may emit light or the first light-emitting devices 21 and the second light-emitting devices 22 may emit light at the same time, where L1<L2. The first mode may be a low grayscale display mode, and the second mode may be a non-low grayscale display mode. When displaying the same brightness, the driving current that drives the first light-emitting devices 21 to emit light may be larger than the driving current that drives the second light-emitting devices 22 to emit light. In the low grayscale display mode, the difference caused by the change in the characteristics of the thin film transistor in the pixel circuit electrically connected to it caused by the reduction in the driving current that drives the first light-emitting device s21 to emit light may be relatively small. In the low grayscale display mode, the first light-emitting devices 21 may emit light, and the second light-emitting devices 22 may not emit light, such that the local uniformity and contrast uniformity of the display panel may be improved when displaying. Further, since the lateral leakage phenomenon of the first light-emitting devices 21 may be lighter than that of the second light-emitting devices 22, in the low grayscale display mode, the first light-emitting devices 21 may emit light, and the second light-emitting devices 22 may not emit light, which may effectively reduce the influence of the leakage current crosstalk on the color gamut and the overall display effect, thereby improving the low grayscale display effect. At the same time, in the non-low grayscale display mode, the second light-emitting devices 22 may emit light. The second light-emitting devices 22 may have a higher device efficiency and a longer life, thereby improving the luminous efficiency and service life of the display panel. That is, the display panel provided by the embodiments of the present disclosure may take into account high efficiency, long life and low grayscale display effect.

As shown in FIG. 1 and FIG. 2, in some optional embodiments, the display panel may include a plurality of light-emitting device groups 201, and each light-emitting device group 201 may include one first light-emitting device 21 and at least one second light-emitting device 22 arranged adjacent to each other. In one same light-emitting device group 201, the light-emitting color of the first light-emitting device 21 may be the same as the light-emitting color of the at least one second light-emitting device 22.

For example, the display panel may include the plurality of light-emitting device groups 201. Each light-emitting device group may include one first light-emitting device 21 and at least one second light-emitting device 22 having the same light-emitting color, such that the first light-emitting devices 21 and the second light-emitting devices 22 may be evenly arranged in the display panel, thereby ensuring color consistency and uniformity in different areas of the display panel when displaying in a display mode in which the first light-emitting devices 21 emit light and the second light-emitting devices 22 do not emit light, and in another display mode in which the first light-emitting devices 21 do not emit light and the second light-emitting devices 22 emit light.

In one embodiment, one light-emitting device group 201 may include one first light-emitting device 21 and one second light-emitting device 22 arranged adjacent to each other. Therefore, in the display mode in which the first light-emitting device 21 emits light and the second light-emitting device 22 does not emit light, and in the display mode in which the first light-emitting device 21 does not emit light and the second light-emitting device 22 emits light, the display panel may have the same resolution when displaying.

Of course, in other embodiments of the present disclosure, each light-emitting device group 201 may also include one first light-emitting device 21 and two or more second light-emitting devices 22 with the same light-emitting color. In yet some other embodiments, each light-emitting device group 201 may also include one second light-emitting device 22 and two or more first light-emitting devices 21, which may be specifically set according to the resolution requirements, and the present disclosure will not be repeated here.

As shown in FIG. 1, in some optional embodiments, in one same light-emitting device group 201, the area of the vertical projection pattern of the first light-emitting device 21 on the base substrate 10 may be equal to the area of the vertical projection pattern of the second light-emitting device 22 on the base substrate 10.

In the same light-emitting device group 201, the area of the vertical projection pattern of the first light-emitting device 21 on the base substrate 10 may be the same as the area of the vertical projection pattern of the second light-emitting device 22 on the base substrate 10. In the display mode where the first light-emitting device 21 emits light and the second light-emitting device 22 emits light, the light intensity distribution of the display panel when emitting light may be more uniform, which helps to reduce the phenomenon of uneven brightness and improve the overall brightness uniformity of the display panel.

At the same time, the area of the vertical projection pattern of the first light-emitting device 21 on the base substrate 10 may be the same as the area of the vertical projection pattern of the second light-emitting device 22 on the base substrate 10, which means that consistent standards and processes may be used in the manufacturing process of the first light-emitting device 21 and the second light-emitting device 22, which simplifies the production and quality control process, is conducive to improving production efficiency and reducing manufacturing costs.

It should be noted that the area of the vertical projection pattern of one light-emitting device 20 on the base substrate 10 may be the area of the vertical projection pattern of the effective light-emitting area of the light-emitting device 20 on the base substrate 10.

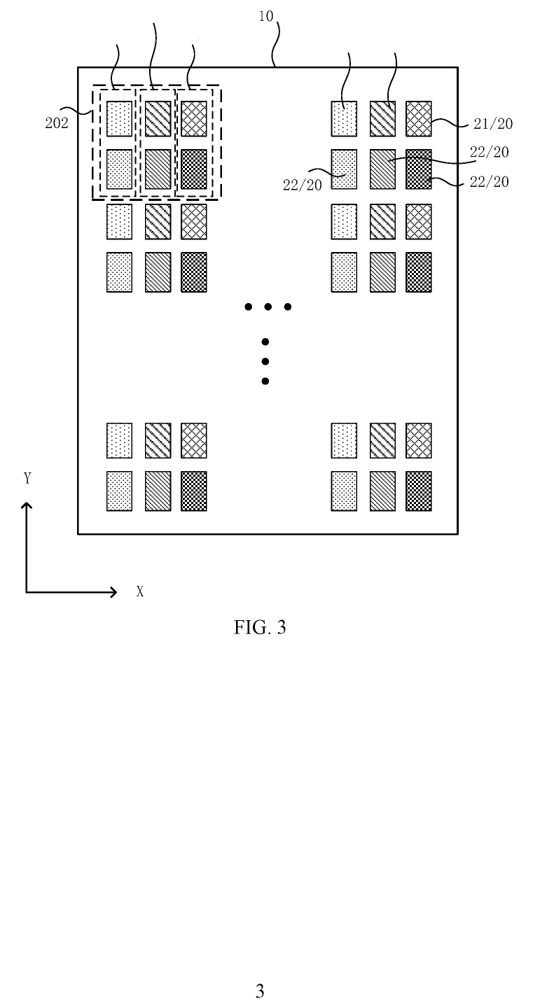

In some embodiments, as shown in FIG. 3 which is a schematic plan view of another display panel, in one same light-emitting device group 201, the area of the vertical projection pattern of the first light-emitting device 21 on the base substrate 10 may be smaller than the area of the vertical projection pattern of the second light-emitting device 22 on the base substrate 10.

When first light-emitting devices 21 of different sizes display the same brightness, when the area of the vertical projection pattern of the first light-emitting device 21 on the base substrate 10 is smaller, the driving current used to drive the first light-emitting device 21 to emit light may be larger. The area of the vertical projection pattern of the first light-emitting device 21 on the base substrate 10 may be smaller than the area of the vertical projection pattern of the second light-emitting device 22 on the base substrate 10, that is, the area of the vertical projection pattern of the first light-emitting device 21 on the base substrate 10 may be smaller. In the low grayscale display mode, the difference caused by the change in the characteristics of the thin film transistors in the pixel circuits electrically connected to it because of the decrease in the driving current driving the first light-emitting device 21 to emit light may be relatively small, such that the local uniformity and contrast uniformity of the display panel is improved in the low grayscale display mode when the first light-emitting device 21 emits light and the second light-emitting device 22 does not emit light.

As shown in FIG. 1 and FIG. 2, in some optional embodiments, in the same light-emitting device group 201, the first light-emitting layer 213 in the first light-emitting device 21 and the second light-emitting layer 223 in the second light-emitting device 22 may be disposed on the same layer.

For example, in the same light-emitting device group 201, the light-emitting color of the first light-emitting device 21 may be the same as the light-emitting color of the second light-emitting device 22, such that the first light-emitting layer 213 in the first light-emitting device 21 and the second light-emitting layer 223 in the second light-emitting device 22 in the same light-emitting device group 201 may be made of the same material in the same process, which is conducive to reducing the process and reducing the production cost.

It should be noted that in the same light-emitting device group 201, the first light-emitting layer 213 in the first light-emitting device 21 may be set at the same layer as any second light-emitting layer 223 in the second light-emitting device 22, and the present disclosure does not make specific restrictions on this, and it may be set according to actual production needs.

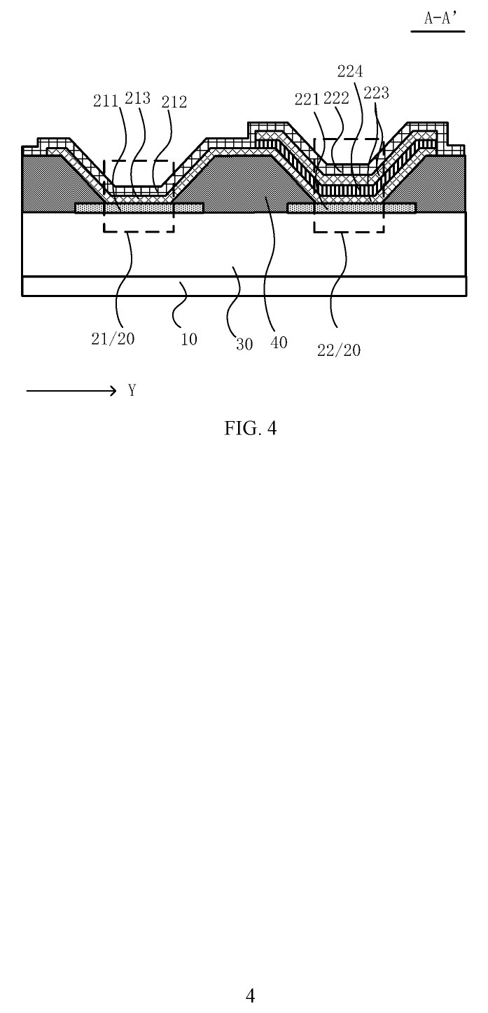

FIG. 4 is another cross-sectional view of the display panel along A-A’ in FIG. 1. As shown in FIG. 1 and FIG. 4, in some optional embodiments, in the same light-emitting device group 201, the first light-emitting layer 213 in the first light-emitting device 21 may be connected to the second light-emitting layer 223 in the second light-emitting device 22.

For example, in the same light-emitting device group 201, the first light-emitting layer 213 in the first light-emitting device 21 and the second light-emitting layer 223 in the second light-emitting device 22 may be made of the same material in the same process. Further, in the same light-emitting device group 201, the first light-emitting layer 213 in the first light-emitting device 21 and the second light-emitting layer 223 in the second light-emitting device 22 may be connected. That is, in the same light-emitting device group 201, the first light-emitting layer 213 in the first light-emitting device 21 and the second light-emitting layer 223 in the second light-emitting device 22 may be obtained by evaporation through the same mask opening, which effectively reduces the difficulty of making the mask plate and reduces the production cost. Moreover, the first light-emitting layer 213 in the first light-emitting device 21 and the second light-emitting layer 223 in the second light-emitting device 22 may be obtained by evaporation through the same mask opening, which is conducive to setting the size of the first light-emitting layer 213 in the first light-emitting device 21 and the second light-emitting layer 223 in the second light-emitting device 22 larger, thereby facilitating improving the aperture ratio of the display panel.

It should be noted that in the same light-emitting device group 201, the first light-emitting layer 213 in the first light-emitting device 21 may be connected to one of the second light-emitting layers 223 in the second light-emitting device 22. In the same light-emitting device group 201, the first anode portion 211 in the first light-emitting device 21 and the second anode portion 221 in the second light-emitting device 22 may be insulated from each other.

As shown in FIG. 1, in some optional embodiments, the display panel may include a plurality of light-emitting device units 202, and one light-emitting device unit 202 may include at least two light-emitting device groups 201 arranged along the first direction X. In one same light-emitting device unit 202, the light-emitting colors of the light-emitting devices 20 in different light-emitting device groups 201 may be different.

For example, the display panel may include a plurality of light-emitting device units 202, and one light-emitting device unit 202 may include at least two light-emitting device groups 201 arranged along a first direction X. In one same light-emitting device unit 202, the light-emitting colors of the light-emitting devices 20 in different light-emitting device groups 201 may be different. Thus, in various display modes, that is, in a display mode in which the first light-emitting device 21 emits light and the second light-emitting device 22 does not emit light, in a display mode in which the first light-emitting device 21 does not emit light and the second light-emitting device 22 emits light, and in a display mode in which the first light-emitting device 21 emits light and the second light-emitting device 22 emits light, the display panel may display pictures of various colors.

Exemplarily, as shown in FIG. 1, the light-emitting device unit 202 may include a first light-emitting device group 2011, a second light-emitting device group 2012, and a third light-emitting device group 2013 arranged along a first direction X. The light-emitting devices 20 in the first light-emitting device group 2011, the light-emitting devices 20 in the second light-emitting device group 2012, and the light-emitting devices 20 in the third light-emitting device group 2013 may have different luminous colors. It should be noted that in other embodiments of the present disclosure, the light-emitting device unit 202 may also include other number of light-emitting device groups 201 arranged along the first direction X, which will not be described in detail in the present disclosure.

As shown in FIG. 1, in some optional embodiments, each light-emitting device 20 in the light-emitting device group 201 may be arranged along the second direction Y, where the first direction X and the second direction Y intersect.

In each light-emitting device group 201, the second light-emitting devices 22 may be located on the same side of the first light-emitting device 21.

For example, in the display panel, when each light-emitting device group 201 in the light-emitting device unit 202 is arranged along the first direction X, each light-emitting device 20 in the light-emitting device group 201 may be arranged along the second direction Y, where the first direction X and the second direction Y intersect. Optionally, the first direction X and the second direction Y may be perpendicular to each other. In each light-emitting device group 201, the second light-emitting device 22 may be located on the same side of the first light-emitting device 21, such that the first light-emitting device 21 and the second light-emitting device 22 may be evenly arranged in the display panel, thereby ensuring the color consistency and uniformity of different areas when the display panel may be displayed in a display mode in which the first light-emitting device 21 emits light and the second light-emitting device 22 does not emit light, and in a display mode in which the first light-emitting device 21 does not emit light and the second light-emitting device 22 emits light. Further, along the second direction Y, one first light-emitting device 21 may be arranged between two adjacent second light-emitting devices 22, and no connecting layer may be arranged in the first light-emitting device 21, such that the arrangement of the first light-emitting device 21 may be conducive to reducing the transmission of the lateral leakage current between the two second light-emitting devices 22 arranged adjacent to each other along the second direction Y, improving the problem of sub-pixel stealing, and improving the display effect.

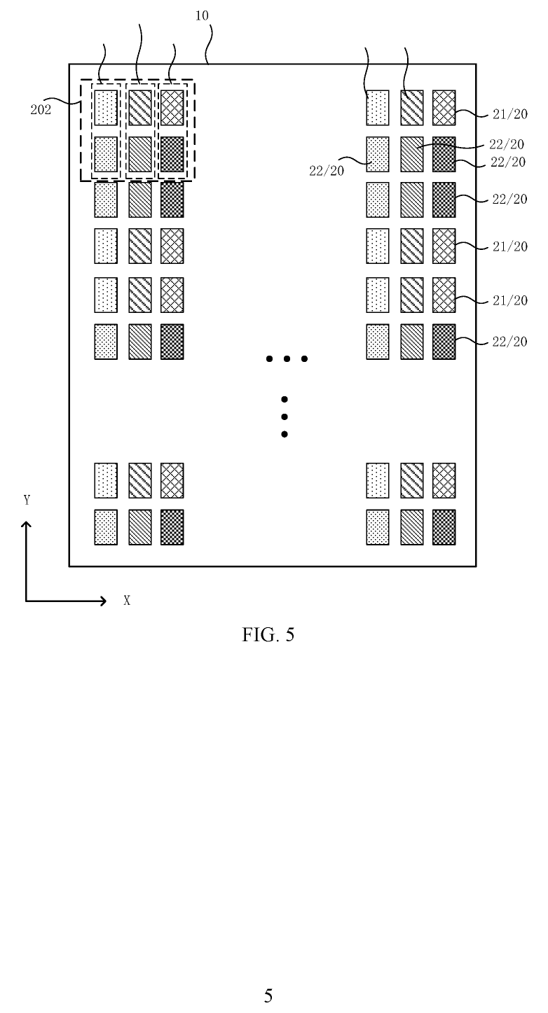

FIG. 5 is a schematic plan view of another display panel provided by the present disclosure. As shown in FIG. 5, in some optional embodiments, each light-emitting device 20 in the light-emitting device group 201 may be arranged along the second direction Y, where the first direction X and the second direction Y intersect.

In two adjacent light-emitting device groups 201 along the second direction Y, the second light-emitting devices 22 may be located on different sides of the first light-emitting device 21.

In the display panel, when each light-emitting device group 201 in the light-emitting device unit 202 is arranged along the first direction X, each light-emitting device 20 in the light-emitting device group 201 may be arranged along the second direction Y, where the first direction X and the second direction Y intersect. And, in two light-emitting device groups 201 adjacent to each other along the second direction Y, the second light-emitting devices 22 may be located on different sides of the first light-emitting device 21, that is, the second light-emitting devices 22 in two light-emitting device groups 201 adjacent to each other along the second direction Y may be arranged adjacently, and the first light-emitting devices 21 in two light-emitting device groups 201 adjacent to each other along the second direction Y may be arranged adjacently. Therefore, more first light-emitting devices 21 may be arranged together, and more second light-emitting devices 22 may be arranged together, which may be conducive to reducing process complexity and improving production efficiency.

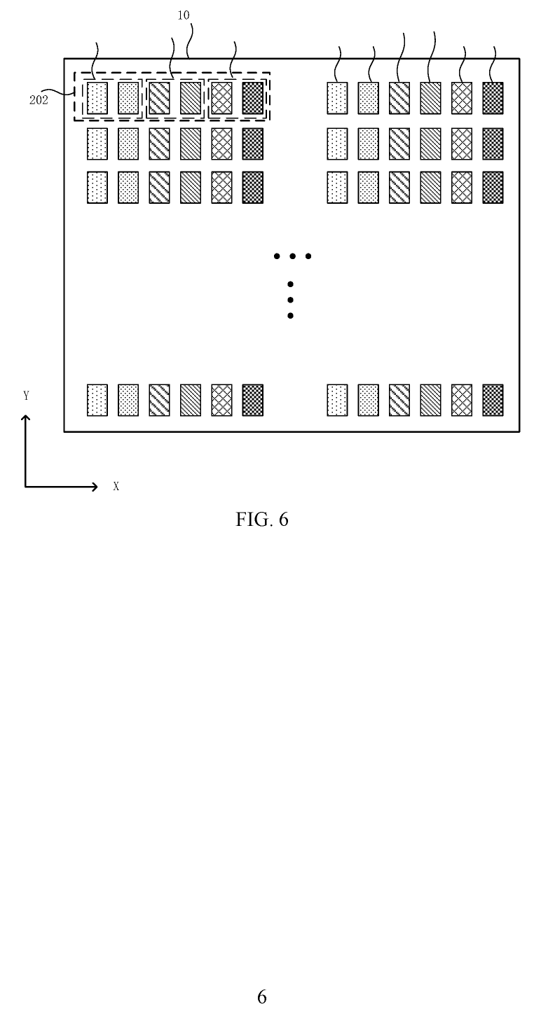

FIG. 6 is a planar schematic diagram of another display panel provided by the present disclosure. As shown in FIG. 6, in some optional embodiments, each light-emitting device 20 in the light-emitting device group 201 may be arranged along the first direction X.

In each light-emitting device group 201, the second light-emitting device 22 may be located on the same side of the first light-emitting device 21.

In the display panel, when each light-emitting device group 201 in the light-emitting device unit 202 is arranged along the first direction X, each light-emitting device 20 in the light-emitting device group 201 may be arranged along the first direction X; and, in each light-emitting device group 201, the second light-emitting device 22 may be located on the same side of the first light-emitting device 21, such that the first light-emitting device 21 and the second light-emitting device 22 may be evenly arranged in the display panel. Therefore, in the display mode where the first light-emitting device 21 emits light and the second light-emitting device 22 does not emit light, and in the display mode where the first light-emitting device 21 does not emit light and the second light-emitting device 22 emits light, the color consistency and uniformity of different areas when the display panel displays may be ensured. Further, along the first direction X, one first light-emitting device 21 may be arranged between two adjacent second light-emitting devices 22, and no connecting layer may be arranged in the first light-emitting device 21, such that the arrangement of the first light-emitting device 21 may be conducive to reducing the transmission of the lateral leakage current between the two second light-emitting devices 22 arranged adjacently along the first direction X, improving the problem of sub-pixel stealing, and improving the display effect.

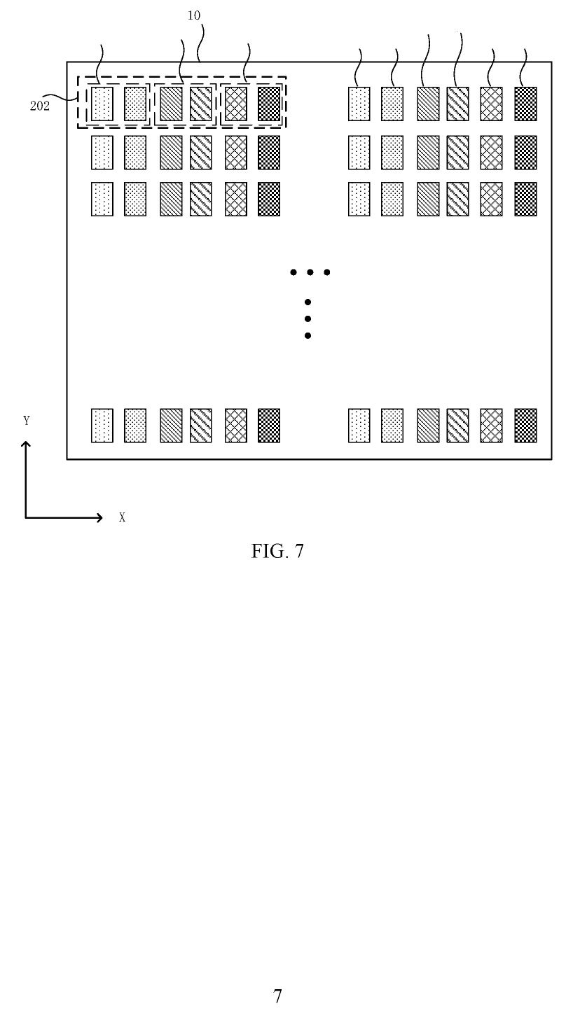

FIG. 7 is a plan view of another display panel provided by the present disclosure. As shown in FIG. 7, in some optional embodiments, each light-emitting device 20 in the light-emitting device group 201 may be arranged along the first direction X.

In two adjacent light-emitting device groups 201 along the first direction X, the second light-emitting devices 22 may be located on different sides of the first light-emitting device 21.

In the display panel, when each light-emitting device group 201 in the light-emitting device unit 202 is arranged along the first direction X, each light-emitting device 20 in the light-emitting device group 201 may be arranged along the first direction X, and in two light-emitting device groups 201 adjacent along the first direction X, the second light-emitting device 22 may be located on different sides of the first light-emitting device 21, that is, the second light-emitting devices 22 in two light-emitting device groups 201 adjacent along the first direction X may be arranged adjacently, and the first light-emitting devices 21 in two light-emitting device groups 201 adjacent along the first direction X may be arranged adjacently. Therefore, more first light-emitting devices 21 may be arranged together, and more second light-emitting devices 22 may be arranged together, which is conducive to reducing process complexity and improving production efficiency.

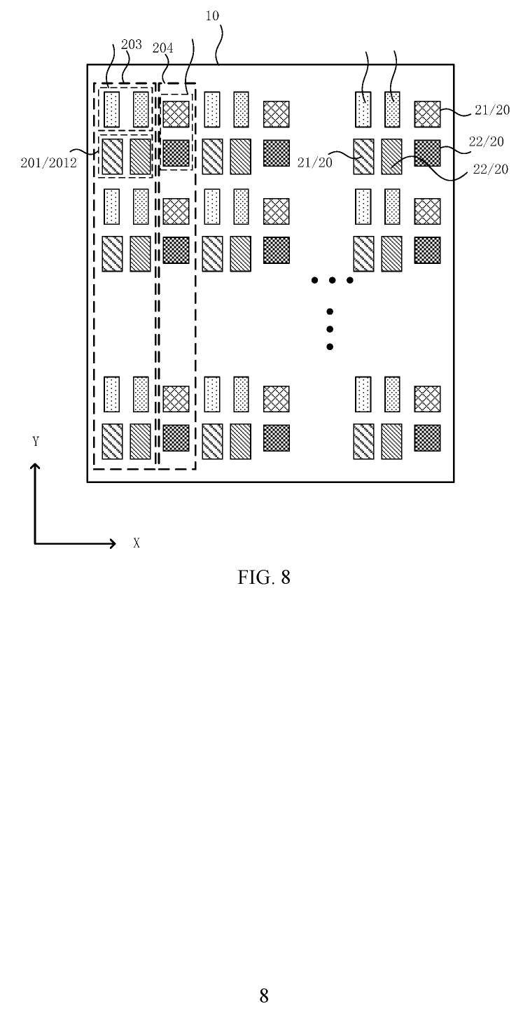

FIG. 8 is a plan view of another display panel provided by the present disclosure. As shown in FIG. 8, in some optional embodiments, the light-emitting device groups 201 may include a first light-emitting device group 2011, a second light-emitting device group 2012, and a third light-emitting device group 2013. The light-emitting colors of the light-emitting devices 20 in the first light-emitting device group 2011, the light-emitting colors of the light-emitting devices 20 in the second light-emitting device group 2012, and the light-emitting colors of the light-emitting devices 20 in the third light-emitting device group 2013 may all be different;

The display panel includes first light-emitting device group columns 203 and second light-emitting group columns 204 alternately and repeatedly arranged along a first direction X.

One first light-emitting device group 203 may include a first light-emitting device group 2011 and a second light-emitting device group 2012 alternately and repeatedly arranged along the second direction Y, and one second light-emitting device group 204 may include a plurality of third light-emitting device groups 2013 arranged along the second direction Y, where the first direction X and the second direction Y intersect;

Each light-emitting device 20 in the first light-emitting device group 2011 and the second light-emitting device group 2012 may be arranged along the first direction X, and each light-emitting device 20 in the third light-emitting device group 2013 may be arranged along the second direction Y.

The display panel may include first light-emitting device group columns 203 and second light-emitting device group columns 204 alternately and repeatedly arranged along a first direction X. One first light-emitting device group column 203 includes a first light-emitting device group 2011 and a second light-emitting device group 2012 alternately and repeatedly arranged along a second direction Y, one second light-emitting device group column 204 may include a plurality of third light-emitting device groups 2013 arranged along the second direction Y. The light-emitting colors of the light-emitting devices 20 in the first light-emitting device group 2011, the light-emitting colors of the light-emitting devices 20 in the second light-emitting device group 2012, and the light-emitting colors of the light-emitting devices 20 in the third light-emitting device group 2013 may all be different. Each light-emitting device 20 in the first light-emitting device group 2011 and the second light-emitting device group 2012 may be arranged along the first direction X, and each light-emitting device 20 in the third light-emitting device group 2013 may be arranged along the second direction Y. The first light-emitting devices 21 with different light-emitting colors and the second light-emitting devices 22 with different light-emitting colors may be evenly arranged in the display panel. Therefore, in various display modes, that is, in a display mode in which the first light-emitting device 21 emits light and the second light-emitting device 22 does not emit light, in a display mode in which the first light-emitting device 21 does not emit light and the second light-emitting device 22 emits light, and in a display mode in which the first light-emitting device 21 emits light and the second light-emitting device 22 emits light, the display panel may be able to display pictures of various colors.

When the number of the third light-emitting device groups 2013 in the second light-emitting device group column 204 is less than the sum of the number of the first light-emitting device groups 2011 and the second light-emitting device groups 2012 in the first light-emitting device group column 203, each light-emitting device 20 in the third light-emitting device groups 2013 may be arranged along the second direction Y, which is conducive to improving the space utilization of the display panel.

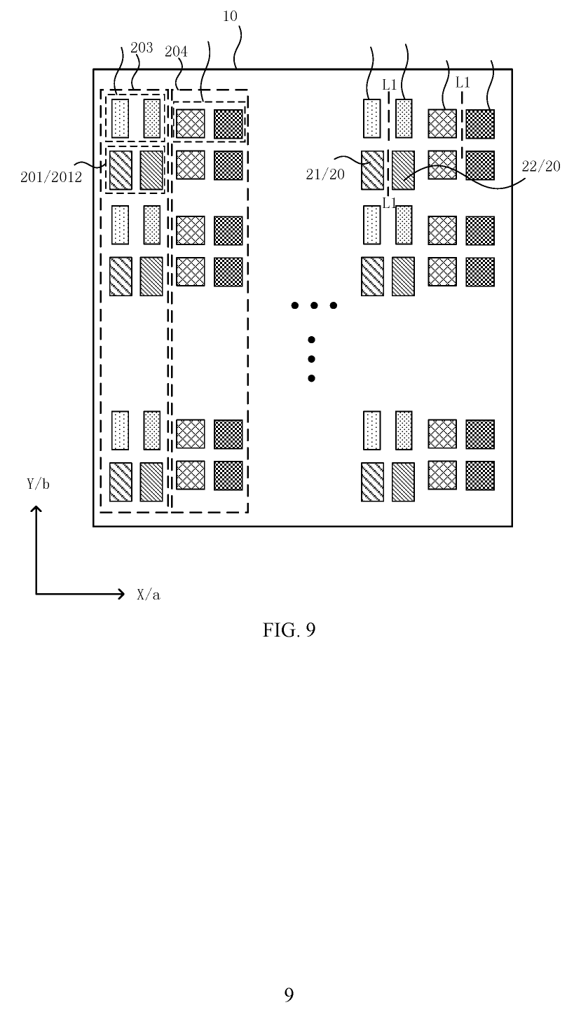

FIG. 9 may be a planar schematic diagram of another display panel provided by the present disclosure. As shown in FIG. 9, in some optional embodiments, the light-emitting device group 201 may include the first light-emitting device group 2011, the second light-emitting device group 2012 and the third light-emitting device group 2013. The light-emitting color of the light-emitting devices 20 in the first light-emitting device group 2011, the light-emitting color of the light-emitting devices 20 in the second light-emitting device group 2012 and the light-emitting colors of the light-emitting device 20 in the third light-emitting device group 2013 may be all different;

The display panel may include first light-emitting device group columns 203 and second light-emitting device group columns 204 alternately and repeatedly arranged along the first direction X.

One first light-emitting device group 203 may include first light-emitting device groups 2011 and second light-emitting device groups 2012 alternately and repeatedly arranged along the second direction Y, and one second light-emitting device group column 204 may include a plurality of third light-emitting device groups 2013 arranged along the second direction Y, where the first direction X and the second direction Y intersect.

Each light-emitting device 20 in the first light-emitting device groups 2011 and the second light-emitting device groups 2012 may be arranged along the first direction X, and each light-emitting device 20 in the third light-emitting device groups 2013 may be arranged along the first direction X.

The display panel may include first light-emitting device group columns 203 and second light-emitting device group columns 204 alternately and repeatedly arranged along a first direction X. One first light-emitting device group column 203 may include first light-emitting device groups 2011 and second light-emitting device groups 2012 alternately and repeatedly arranged along a second direction Y. One second light-emitting device group column 204 may include a plurality of third light-emitting device groups 2013 arranged along the second direction Y. The light-emitting colors of the light-emitting devices 20 in the first light-emitting device groups 2011, the light-emitting colors of the light-emitting devices 20 in the second light-emitting device groups 2012, and the light-emitting colors of the light-emitting devices 20 in the third light-emitting device groups 2013 may be all different. The light-emitting devices 20 in the first light-emitting device groups 2011 and the second light-emitting device groups 2012 may be arranged along the first direction X. The light-emitting devices 20 in the third light-emitting device groups 2013 may be arranged along the first direction X. The first light-emitting devices 21 with different light-emitting colors and the second light-emitting devices 22 with different light-emitting colors may be evenly arranged in the display panel. Therefore, in various display modes, that is, in a display mode in which the first light-emitting device 21 emits light and the second light-emitting device 22 does not emit light, in a display mode in which the first light-emitting device 21 does not emit light and the second light-emitting device 22 emits light, and in a display mode in which the first light-emitting device 21 emits light and the second light-emitting device 22 emits light, the display panel may display pictures of various colors.

When the number of the third light-emitting device groups 2013 in the second light-emitting device group column 204 is the same as the sum of the number of the first light-emitting device groups 2011 and the second light-emitting device groups 2012 in the first light-emitting device group column 203, each light-emitting device 20 in the third light-emitting device groups 2013 may be arranged along the first direction X, which may be beneficial to improve the space utilization of the display panel.

As shown in FIG. 9, in some other optional embodiments, each light-emitting device 20 in the light-emitting device groups 201 may be arranged along the first direction X.

In each light-emitting device group 201, the second light-emitting devices 22 may be located on the same side of the first light-emitting devices 21.

In the first light-emitting device group column 203 and the second light-emitting device group column 204, each light-emitting device 20 in each light-emitting device group 201 may be arranged along the first direction X, and in each light-emitting device group 201, the second light-emitting device 22 may be located on the same side of the first light-emitting device 21, such that the first light-emitting devices 21 and the second light-emitting devices 22 may be evenly arranged in the display panel. Therefore, in the display mode where the first light-emitting device 21 emits light and the second light-emitting device 22 does not emit light, and in the display mode where the first light-emitting device 21 does not emit light and the second light-emitting device 22 emits light, the color consistency and uniformity of different areas when the display panel may be displayed may be ensured. At the same time, along the first direction X, one first light-emitting device 21 may be arranged between two adjacent second light-emitting devices 22, and no connecting layer may be arranged in the first light-emitting device 21, such that the arrangement of the first light-emitting device 21 may be conducive to reducing the transmission of the lateral leakage current between the two second light-emitting devices 22 arranged adjacent to each other along the first direction X, improving the problem of sub-pixel stealing, and improving the display effect.

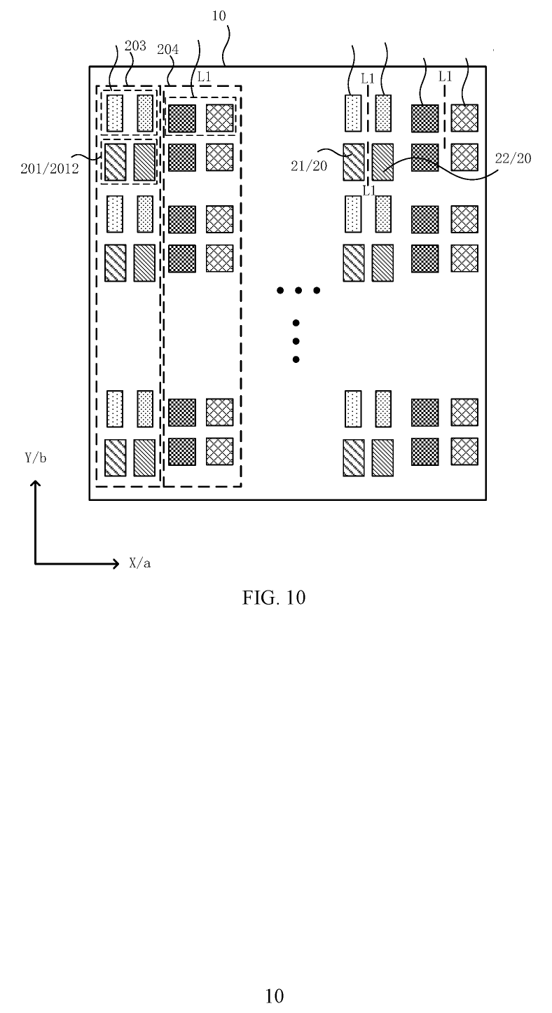

FIG. 10 is a planar schematic diagram of another display panel provided by the present disclosure. As shown in FIG. 10, in some optional embodiments, each light-emitting device 20 in the light-emitting device group 201 may be arranged along the first direction X.

In two light-emitting device groups 201 adjacent along the first direction X, the second light-emitting devices 22 may be located on different sides of the first light-emitting devices 21.

In the first light-emitting device group column 203 and the second light-emitting device group column 204, each light-emitting device 20 in the light-emitting device group 201 may be arranged along the first direction X, and in two light-emitting device groups 201 adjacent along the first direction X, the second light-emitting devices 22 may be located on different sides of the first light-emitting devices 21, that is, there may be some second light-emitting devices 22 in two light-emitting device groups 201 adjacent along the first direction X, and there may be some first light-emitting devices 21 in two light-emitting device groups 201 adjacent along the first direction X. Therefore, more first light-emitting devices 21 may be arranged together, and more second light-emitting devices 22 may be arranged together, which may be conducive to reducing process complexity and improving production efficiency.

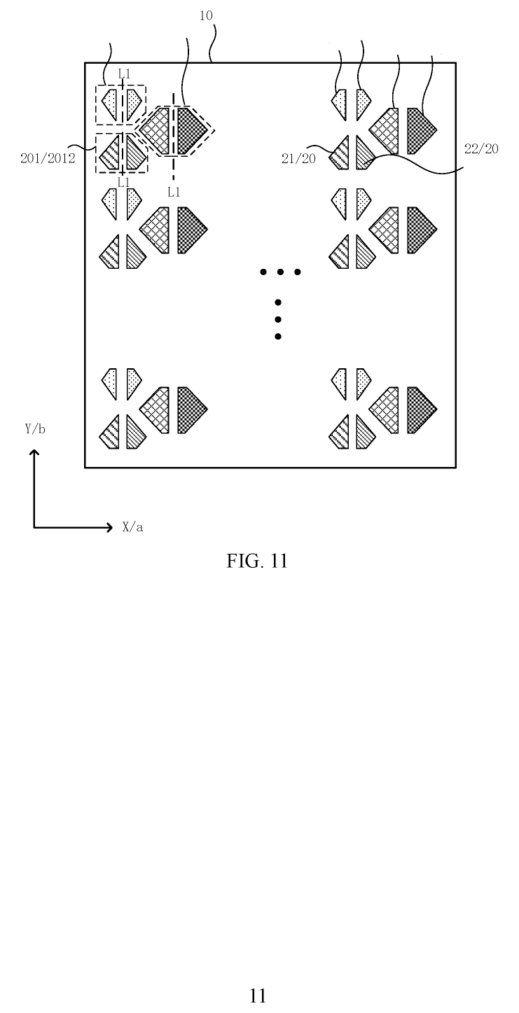

FIG. 11 is a plan view of another display panel provided by the present disclosure. As shown in FIG. 11, in some optional embodiments, one light-emitting device group 20 may include a first light-emitting device 21 and a second light-emitting device 22 arranged adjacent to each other.

In the same light-emitting device group 20, the first light-emitting device 21 and the second light-emitting device 22 may be arranged along the third direction a, and the vertical projection pattern of the first light-emitting device 21 on the base substrate 10 may be symmetrical with the vertical projection pattern of the second light-emitting device 22 on the base substrate 10 along the first symmetry axis L1, where the first symmetry axis L1 extends along a fourth direction b and the third direction a and the fourth direction b intersect.

As shown in FIG. 11, when the light-emitting device group 20 includes a first light-emitting device 21 and a second light-emitting device 22 adjacent to each other, in the same light-emitting device group 20, the first light-emitting device 21 and the second light-emitting device 22 may be arranged along a third direction a, and a vertical projection pattern of the first light-emitting device 21 on the base substrate 10 may be symmetrical with a vertical projection pattern of the second light-emitting device 22 on the base substrate 10 along a first symmetry axis L1. In the display mode in which the first light-emitting device 21 emits light and the second light-emitting device 22 emits light, the visual effect of the display panel may be effectively improved, making the display more uniform and beautiful.

In particular, when the vertical projection pattern of the first light-emitting device 21 on the base substrate 10 and the vertical projection pattern of the second light-emitting device 22 on the base substrate 10 are in the shape of a triangle, a polygon or an irregular shape, the vertical projection pattern of the first light-emitting device 21 on the base substrate 10 and the vertical projection pattern of the second light-emitting device 22 on the base substrate 10 may be symmetrical along the first symmetry axis L1. Therefore, in the display mode where the first light-emitting device 21 emits light and the second light-emitting device 22 emits light, the visual effect of the display panel can be effectively improved, making the display more uniform and beautiful.

It should be noted that FIG. 11 exemplarily shows the shape of the vertical projection pattern of each first light-emitting device 21 on the base substrate 10 and the vertical projection pattern of each second light-emitting device 22 on the base substrate 10 in the display panel. In other embodiments of the present disclosure, the vertical projection pattern of each first light-emitting device 21 on the base substrate 10 and the vertical projection pattern of each second light-emitting device 22 on the base substrate 10 may also be other shapes, which will not be described one by one in the present disclosure.

It should be understood that FIG. 11 exemplarily shows that the third direction a is the same as the first direction X, and the fourth direction b is the same as the second direction Y. In other embodiments of the present disclosure, the third direction a and the first direction X may also be different, and the fourth direction b and the second direction Y may also be different. The present disclosure will not repeat them one by one here.

It should be noted that FIG. 11 exemplarily shows that when the vertical projection pattern of each first light-emitting device 21 in the display panel on the base substrate 10 and the vertical projection pattern of each second light-emitting device 22 on the base substrate 10 are polygonal in shape, in the same light-emitting device group 20, the first light-emitting device 21 and the second light-emitting device 22 are arranged along the third direction a, and the vertical projection pattern of the first light-emitting device 21 on the base substrate 10 and the vertical projection pattern of the second light-emitting device 22 on the base substrate 10 are symmetrical along the first symmetry axis L1. In other embodiments of the present disclosure, exemplarily, as shown in FIG. 9 and FIG. 10, when the vertical projection pattern of the first light-emitting device 21 on the base substrate 10 and the vertical projection pattern of each second light-emitting device 22 on the base substrate 10 are in a rectangular shape, in the same light-emitting device group 20, the first light-emitting device 21 and the second light-emitting device 22 may be arranged along the third direction a, and the vertical projection pattern of the first light-emitting device 21 on the base substrate 10 and the vertical projection pattern of the second light-emitting device 22 on the base substrate 10 may be symmetrical along the first symmetry axis L1. Of course, the vertical projection pattern of the first light-emitting device 21 on the base substrate 10 and the vertical projection pattern of each second light-emitting device 22 on the base substrate 10 may also be in other shapes. In this case, in the same light-emitting device group 20, the first light-emitting device 21 and the second light-emitting device 22 may be arranged along the third direction a, and the vertical projection pattern of the first light-emitting device 21 on the base substrate 10 and the vertical projection pattern of the second light-emitting device 22 on the base substrate 10 may be symmetrical along the first symmetry axis L1, and the present disclosure will not repeat them one by one here.

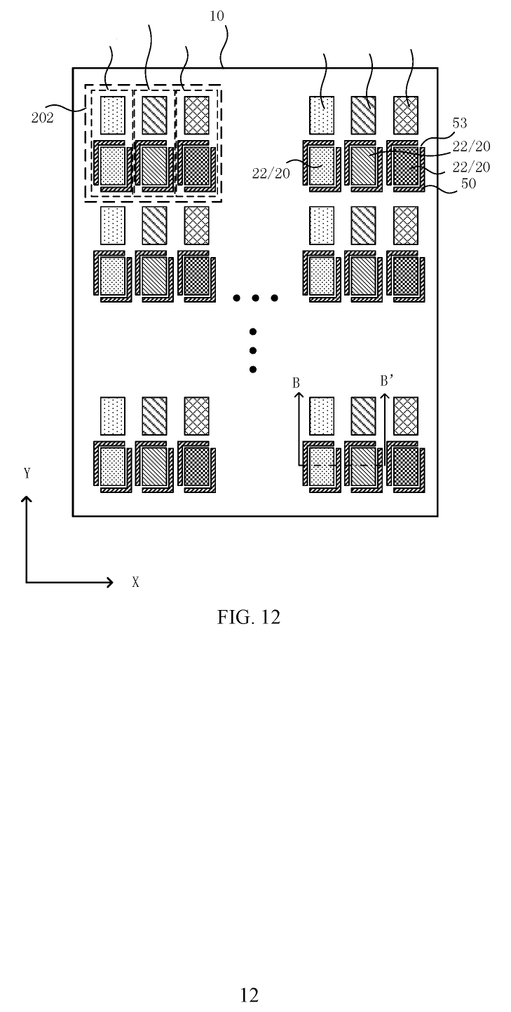

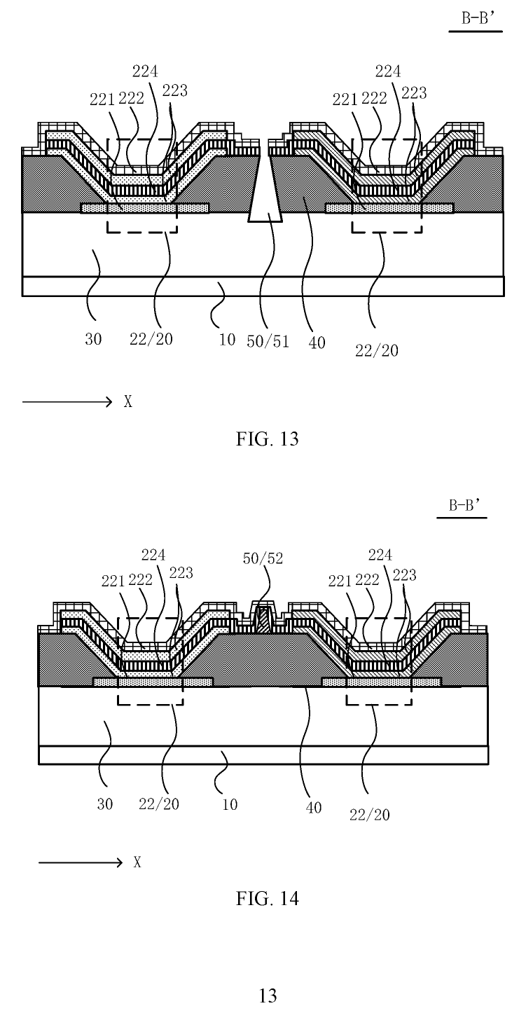

FIG. 12 is a plan view of another display panel provided by the present disclosure, and FIG. 13 is a cross-sectional view of the display panel described in FIG. 12 along B-B’. As shown in FIG. 12 and FIG. 13, in some optional embodiments, the display panel may further include a plurality of partitions 50, and at least one partition 50 may be disposed between two adjacent second light-emitting devices 22.

The second light-emitting device 22 may include a connecting layer 224. Since the connecting layers 224 in the adjacent second light-emitting devices 22 are connected to each other, current may flow from one second light-emitting device 22 to another adjacent second light-emitting device 22 through the connecting layers 224, that is, a lateral leakage current may be generated, such that the second light-emitting device 22 that should not emit light may emit light in response to the current flowing from the adjacent second light-emitting device 22, resulting in a stealth problem, which reduces the display effect of the display panel.

The display panel may be provided with the first light-emitting devices 21 and the second light-emitting devices 22 at the same time, that is, part of the second light-emitting devices 22 may be arranged adjacent to the first light-emitting devices 21. The first light-emitting device 21 may not be provided with a connecting layer 224, such that the arrangement of the first light-emitting device 21 is conducive to reducing the transmission of the lateral leakage current between the second light-emitting devices 22, improving the problem of sub-pixel stealing, and improving the display effect.

The display panel may also include a plurality of partitions 50, and at least one partition 50 may be arranged between two adjacent second light-emitting devices 22. Optionally, one partition 50 may include a groove 51, and the groove 51 may at least partially penetrate the pixel definition layer 40 along the direction perpendicular to the plane where the base substrate 10 is located. Therefore, when the connecting layer 224 is subsequently evaporated, the arrangement of the groove 51 may increase the path length of the connecting layer 224, and the inclined surface of the inner wall of the groove 51 may cause the thickness of the connecting layer 224 to be thinned or even cause the connecting layer 224 to be truncated, thereby effectively hindering the transmission of the lateral leakage current between the two adjacent second light-emitting devices 22, improving the problem of sub-pixel stealing, and improving the display effect.

FIG. 14 is another cross-sectional view of the display panel described in FIG. 12 along B-B’. As shown in FIG. 12 and FIG. 14, the display panel may further include a plurality of partitions 50, and at least one partition 50 may be provided between two adjacent second light-emitting devices 22. Optionally, one partition 50 may include a protruding structure 52, and the protruding structure 52 may be located on the side of the pixel definition layer 40 away from the base substrate 10. Therefore, when the connection layer 224 is subsequently evaporated, the portion of the connection layer 224 covering the protruding structure 52 may be a ridge structure. The provision of the protruding structure 52 may increase the path length of the connection layer 224, and the inclined surface of the protruding structure 52 may cause the thickness of the connection layer 224 to be thinned, thereby effectively hindering the transmission of the lateral leakage current between the two adjacent second light-emitting devices 22, improving the problem of sub-pixel stealing, and improving the display effect.

As shown in FIG. 12, in some optional embodiments, one partition 50 may be provided corresponding to one second light-emitting device 22, and the vertical projection of the partition 50 on the base substrate 10 may at least partially surround the vertical projection of the corresponding second light-emitting device 22 on the base substrate 10.

The partition 50 may be arranged corresponding to the second light-emitting device 22, and the vertical projection of partition 50 on the base substrate 10 may at least partially surround the vertical projection of the corresponding second light-emitting device 22 on the base substrate 10. The partition 50 may effectively hinder the transmission of the lateral leakage current between the second light-emitting device 22 and the light-emitting device 20 adjacent to it, improve the problem of sub-pixel stealing, and improve the display effect. At the same time, it may be only necessary to set partitions 50 around the second light-emitting devices 22, and it may be unnecessary to set partitions 50 around the first light-emitting devices 21, which reduces the number of partitions 50, thereby reducing the layout complexity, simplifying the overall structure, and reducing the process difficulty. In addition, the partitions 50 may not be set around the first light-emitting devices 21, such that more space may be released for the light-emitting area, which may be conducive to improving the aperture ratio.

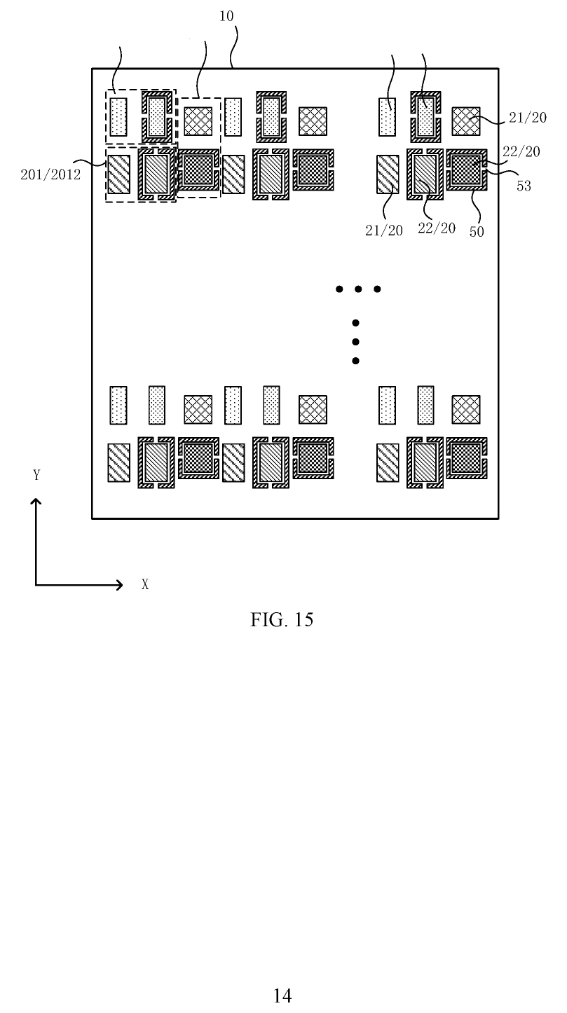

FIG. 15 is a plan view of another display panel provided by the present disclosure. As shown in FIG. 15, in some optional embodiments, the vertical projection pattern of one partition 50 on the base substrate 10 may include a notch 53.

The notches 53 of the vertical projection pattern of two adjacent partition 50 on the base substrate 10 may be set in different orientations.

The vertical projection pattern of one partition 50 on the base substrate 10 may be a non-closed figure including the notch 53. The setting of the notch 53 may form a continuous structure of the cathode portion at the corresponding position of the notch 53 to avoid signals that cannot be transmitted to the cathode portion. At the same time, a transistor connected to the anode portion may be set at the corresponding position of the notch 53. When the partition 50 includes a groove, the setting of the partition 50 may be prevented from affecting the setting of the transistor.

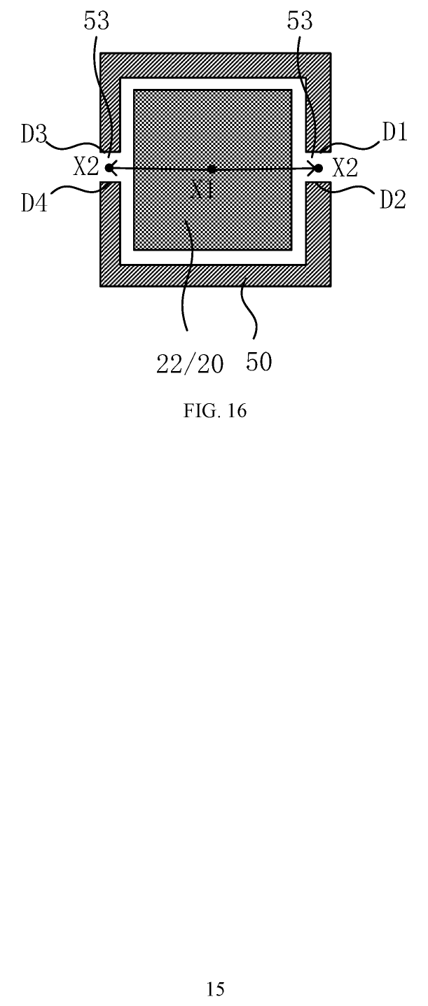

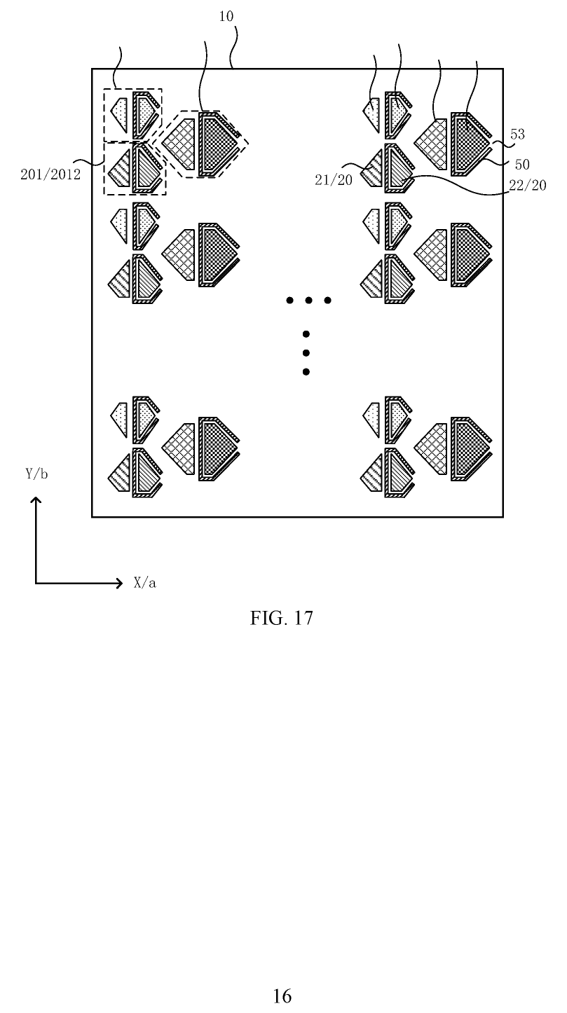

As shown in FIG. 16, which shows a positional relationship diagram of a second light-emitting device and a partition provided by the present disclosure, the orientation of the notch 53 of the vertical projection pattern of the partition 50 on the base substrate 10 may be the direction in which the center of gravity X1 of the vertical projection of the second light-emitting device 22 corresponding to the partition 50 on the plane where the base substrate 10 is located points to the center X2 of the notch 53, that is, the arrow shown by X1X2, where the center X2 of the notch 53 refers to the midpoint of the line connecting two adjacent endpoints in the partition 50 forming the notch 53. As shown in FIG. 16, the partition 50 may include a first endpoint D1, a second endpoint D2, a third endpoint D3, and a fourth endpoint D4. One notch 53 may be located between the first endpoint D1 and the second endpoint D2, and one notch 53 may be located between the third endpoint D3 and the fourth endpoint D4. The midpoint of the line connecting the first endpoint D1 and the second endpoint D2 is the center X2 of the notch 53, and the midpoint of the line connecting the third endpoint D3 and the fourth endpoint D4 may be the center X2 of the notch 53.

When the vertical projection of the second light-emitting device 22 on the plane where the base substrate 10 is located is a regular shape, the center of gravity X1 of the vertical projection of the second light-emitting device 22 on the plane where the base substrate 10 is located may be the center of the vertical projection of the second light-emitting device 22 on the plane where the base substrate 10 is located.

The center of gravity of the vertical projection of the second light-emitting device 22 on the plane where the base substrate 10 is located may be defined as the center point of mass distribution of the geometric shape of the vertical projection of the second light-emitting device 22 on the plane where the base substrate 10 is located, that is, the center of mass. When the geometric shape of the vertical projection of the second light-emitting device 22 on the plane where the base substrate 10 is located is a regular geometric shape, the geometric center of the vertical projection of the second light-emitting device 22 on the plane where the base substrate 10 is located may coincide with its center of gravity. For example, the shape of the vertical projection of the second light-emitting device 22 on the plane where the base substrate 10 is located may be a parallelogram, and the intersection of the two diagonals of the parallelogram may be its geometric center and its center of gravity. When the geometric shape of the vertical projection of the second light-emitting device 22 on the plane where the base substrate 10 is located is an asymmetric irregular geometric shape, its center of gravity may be determined by relevant technology, while its geometric center may be difficult to determine. At this time, the relative position relationship between the geometric center and the center of gravity of the vertical projection of the second light-emitting device 22 on the plane where the base substrate 10 is located may be difficult to determine. The regular figures(regular geometric shapes) in the present may meet at least one of the following conditions: 1) central symmetric figures; 2) axisymmetric figures with more than two axes of symmetry. For example, ellipses, parallelograms (non-rectangular and non-rhombus), circles, rounded rectangles, regular polygons, rectangles, rhombuses, etc. are all regular figures. For central symmetric figures, the central symmetry point may be the center (center of gravity). For axisymmetric figures with more than two axes of symmetry, the intersection of the two axes of symmetry may be the center (center of gravity). Figures other than the corresponding regular figures may be irregular figures.

Notches 53 of the vertical projection pattern of two adjacent partitions 50 on the base substrate 10 may be arranged in different orientations, such that the notches 53 of the vertical projection pattern of the two adjacent partitions 50 on the base substrate 10 may be avoided to be arranged relative to each other, and thus the lateral leakage current between the two adjacent second light-emitting devices 22 may be avoided to be transmitted through the corresponding part of the notch 53, effectively hindering the transmission of the lateral leakage current between the two adjacent second light-emitting devices 22, improving the problem of sub-pixel stealing, and improving the display effect.

It should be noted that the two adjacent partitions 50 refer to the two partitions 50 between which no light-emitting device 20 is arranged such that that the two partitions 50 are directly adjacent, which is applicable in other embodiments of the present disclosure.

As shown in FIG. 15, in some optional embodiments, the vertical projection pattern of one partition portion 50 on the base substrate 10 may include notches 53, and notches 53 of the vertical projection patterns of two adjacent partition portions 50 on the base substrate 10 may not be arranged opposite to each other, thereby preventing the lateral leakage current between the two adjacent second light-emitting devices 22 from being transmitted through the corresponding part of the notches 53, effectively hindering the transmission of the lateral leakage current between the two adjacent second light-emitting devices 22, improving the problem of sub-pixel stealing, and improving the display effect.

In some other optional embodiments, for example, as shown in FIG. 12 and FIG. 17 which is a plan schematic diagram of another display panel provided by the present disclosure, the setting orientations of the notches 53 in the vertical projection pattern of two adjacent partition portions 50 on the base substrate 10 may also be the same, and it may be only necessary to satisfy that the notches 53 in the vertical projection pattern of the two adjacent partition portions 50 on the base substrate 10 are not arranged relative to each other, thereby avoiding the lateral leakage current between the two adjacent second light-emitting devices 22 from being transmitted through the corresponding parts of the gaps 53, effectively hindering the transmission of the lateral leakage current between the two adjacent second light-emitting devices 22, improving the problem of sub-pixel stealing, and improving the display effect.

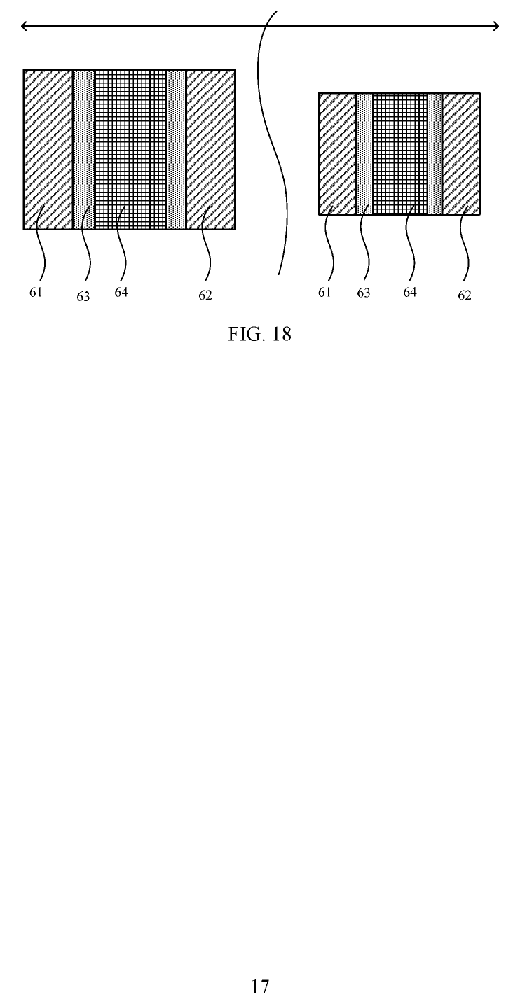

FIG. 18 is a top view of a driving transistor in a first pixel circuit and a driving transistor in a second pixel circuit in a display panel provided by the present disclosure. As shown in FIG. 1 and FIG. 18, in some optional embodiments, the display panel may further include a plurality of pixel circuits, and each pixel circuit may include a driving transistor 60.

The plurality of pixel circuits may include first pixel circuits connected to the first light-emitting devices 21, and second pixel circuits connected to the second light-emitting devices 22. A vertical projection area of a channel of one driving transistor 60 in one first pixel circuit on the base substrate may be larger than a vertical projection area of a channel of one driving transistor 60 in one second pixel circuit on the substrate.

The display panel may further include the plurality of pixel circuits, and each pixel circuit may include one driving transistor 60, and the driving transistor 60 may include a source 61, a drain 62, a gate 63 and an active layer 64. The source 61 and the drain 62 may be electrically connected to two ends of the active layer 64 respectively, and at least one insulating layer may be provided between the active layer 64 and the gate 63, and the overlapping part of the active layer 64 and the gate 63 may be the channel. When the area of the channel is larger, the conductivity of the driving transistor 60 may be larger.

When displaying the same brightness, the driving current driving the first light-emitting device 21 to emit light may be larger than the driving current driving the second light-emitting device 22 to emit light. The driving transistor 60 in the first pixel circuit connected to the first light-emitting device 21 may be the first driving transistor 601, and the driving transistor 60 in the second pixel circuit connected to the second light-emitting device 22 may be the second driving transistor 602. The vertical projection area of the channel of the first driving transistor 601 on the base substrate may be larger than the vertical projection area of the channel of the second driving transistor 602 on the substrate, such that the first driving transistor 601 is able to carry a larger driving current, thereby meeting the higher current demand required by the first light-emitting device 21.

As shown in FIG. 1 and FIG. 18, in some optional embodiments, the vertical projection area of the channel of the driving transistor 60 in the first pixel circuit on the base substrate may be larger than the vertical projection area of the channel of the driving transistor 60 in the second pixel circuit on the substrate. Accordingly, the vertical projection area of the first pixel circuit on the base substrate may be larger than the vertical projection area of the second pixel circuit on the substrate, that is, the vertical projection area of the first pixel circuit on the base substrate may be more extensive, thereby providing a larger space for setting the driving transistor 60 with a larger size in the first pixel circuit, which is conducive to reducing the process difficulty of the first pixel circuit. Further, the vertical projection area of the first pixel circuit on the base substrate is larger, such that the spacing between the transistors in the first pixel circuits may still be set larger when the size of the driving transistor 60 in the first pixel circuit is set larger, thereby reducing the mutual interference between adjacent transistors in the first pixel circuit and improving the stability and reliability of the first pixel circuit. The width of the vertical projection pattern of the first pixel circuit on the base substrate along the second direction Y may be larger than the width of the vertical projection pattern of the second pixel circuit on the base substrate along the second direction Y, and/or, the length of the vertical projection pattern of the first pixel circuit on the base substrate along the first direction X may be larger than the length of the vertical projection pattern of the second pixel circuit on the base substrate along the first direction X.

In other embodiments of the present disclosure, the vertical projection area of the first pixel circuit on the base substrate may be the same as the vertical projection area of the second pixel circuit on the substrate, and it may be only necessary to set the vertical projection area of the channel of the driving transistor 60 in the first pixel circuit on the base substrate to be larger than the vertical projection area of the channel of the driving transistor 60 in the second pixel circuit on the substrate, and the present disclosure will not elaborate on it here.

Optionally, as shown in FIG. 8, when a row of light-emitting devices 20 arranged along the first direction X includes first light-emitting devices 21 and second light-emitting devices 22, in the pixel circuits connected to the same row of light-emitting devices 20, the first pixel circuits connected to the first light-emitting devices 21 may be arranged along the first direction X, and the second pixel circuits connected to the second light-emitting devices 22 may be arranged along the first direction X, while the first pixel circuits and the second pixel circuits may not be arranged along the first direction X. That is, the first pixel circuits connected to the first light-emitting devices 21 may be arranged in one row, and the second pixel circuits connected to the second light-emitting devices 22 may be arranged in another row, such that the wiring paths of the signal lines connected to the first light-emitting devices 21 and the signal line connected to the second light-emitting devices 22 may be separated, which may effectively reduce the coupling effect between the signal lines connected to the first light-emitting devices 21 and the signal lines connected to the second light-emitting devices 22, improve the stability and reliability of signal transmission. Also, the separated wiring paths may be conducive to reducing complex wiring structures, which not only reduces the complexity of wiring design, but also reduces possible errors in the wiring process, improves production efficiency, and reduces production costs. The first pixel circuits connected to the first light-emitting devices 21 may be arranged in one row, and the second pixel circuits connected to the second light-emitting devices 22 may be arranged in another row. Accordingly, the driving circuits may work according to simpler timing logic. For example, only one row of first pixel circuits connected to the first light-emitting devices 21 or only one row of second pixel circuits connected to the second light-emitting devices 22 may be processed at the same time, thereby reducing the complexity of timing control and the difficulty of designing the driving circuits.

The present disclosure also provides a driving method applied to a display panel. The display panel may include: a base substrate 10; a plurality of light-emitting devices 20. The plurality of light-emitting devices 20 may be located on one side of the base substrate 10 and may include first light-emitting devices 21 and second light-emitting devices 22. One first light-emitting device 21 may include a first anode portion 211 and a first cathode portion 212 arranged opposite to each other, and a first light-emitting layer 213 located between the first anode portion 211 and the first cathode portion 212. One second light-emitting device 22 may include a second anode portion 221 and a second cathode portion 222 arranged opposite to each other, and at least two second light-emitting layers 223 located between the second anode portion 221 and the second cathode portion 222. A connecting layer 224 may be arranged between two adjacent second light-emitting layers 223, and in the same second light-emitting device 22, the light-emitting colors of each second light-emitting layer 223 may be the same.

The driving method may include:

in the first mode, the brightness of the display panel is L1, the first light-emitting device 21 emits light, and the second light-emitting device 22 does not emit light; and

in the second mode, the brightness of the display panel is L2, the second light-emitting device 22 emits light, or the first light-emitting device 21 and the second light-emitting device 22 emit light at the same time, where L1＜L2.

In one embodiment, the display panel may include the first light-emitting devices 21 and the second light-emitting devices 22. One first light-emitting device 21 may include a first anode portion 211 and a first cathode portion 212 arranged opposite to each other, and a first light-emitting layer 213 located between the first anode portion 211 and the first cathode portion 212. That is, the first light-emitting device 21 may be a single-layer light-emitting device.

The second light-emitting device 22 may include a second anode portion 221 and a second cathode portion 222 arranged opposite to each other, and at least two layers of second light-emitting layers 223 located between the second anode portion 221 and the second cathode portion 222. A connecting layer 224 may be arranged between two adjacent layers of the second light-emitting layers 223, and in the same second light-emitting device 22, the light-emitting colors of each second light-emitting layer 223 may be the same. That is, the second light-emitting device 22 may be a stacked light-emitting device. The second light-emitting device 22 may include at least two light-emitting units connected in series, and the adjacent light-emitting units may be connected by one corresponding connecting layer 224, and the stacked light-emitting device may have a higher device efficiency and a longer life.

When displaying the same brightness, the driving current driving the first light-emitting device 21 to emit light may be larger than the driving current driving the second light-emitting device 22 to emit light. Therefore, in the low grayscale display mode, the difference caused by the change in the characteristics of the thin film transistor in the pixel circuit electrically connected to it because of the decrease in the driving current driving the first light-emitting device 21 to emit light may be relatively small.

The display panel provided by the embodiment of the present disclosure may be provided with the first light-emitting devices 21 and the second light-emitting devices 22 at the same time. The first light-emitting devices 21 and the second light-emitting devices 22 may be different types of light-emitting devices 20. One first light-emitting device 21 may be a single-layer light-emitting device and one second light-emitting device 22 may be a stacked light-emitting device, such that the light-emitting state of the two light-emitting devices 20 may be flexibly changed according to the application scenario or usage requirements. For example, in a scenario with high brightness requirements, the second light-emitting device 22 may be mainly relied on for light emission. The stacked light-emitting device usually has higher light-emitting efficiency and longer service life. In low power consumption or low grayscale display, the first light-emitting device 21 may be used more for light emission. The single-layer light-emitting device may perform well in low grayscale display and may provide better contrast and color reproduction. This design supports multiple display modes, and is able to operate in a high-efficiency mode or in a mode requiring a long life and a high low grayscale display effect, thereby taking into account high efficiency, long life and low grayscale display effects, to meet the needs of different users and applications.

For example, the display panel provided by the present disclosure may have the first mode and the second mode. In the first mode, the brightness of the display panel may be L1, and in the second mode, the brightness of the display panel may be L2, where L1＜L2. That is, the first mode may be a low grayscale display mode, and the second mode may be a non-low grayscale display mode.

In the low grayscale display mode, the difference caused by the change in the characteristics of the thin film transistor in the pixel circuit electrically connected to the first light-emitting device 21 caused by the reduction of the driving current that drives the first light-emitting device 21 to emit light may be relatively small. In the low grayscale display mode, the first light-emitting device 21 may emit light, and the second light-emitting device 22 may not emit light, such that the local uniformity and contrast uniformity of the display panel may be improved. Further, since the lateral leakage phenomenon of the first light-emitting device 21 may be lighter than the lateral leakage phenomenon of the second light-emitting device 22, in the low grayscale display mode, the first light-emitting device 21 may emit light, and the second light-emitting device 22 may not emit light, which may effectively reduce the influence of the leakage crosstalk on the color gamut and the overall display effect, thereby improving the low grayscale display effect. At the same time, in the non-low grayscale display mode, the second light-emitting device 22 may emit light, and the second light-emitting device 22 may have a higher device efficiency and a longer life, thereby improving the light-emitting efficiency and service life of the display panel. That is, the display panel provided by the embodiments of the present disclosure may take into account high efficiency, long life and low grayscale display effect.

The boundary between the low grayscale display mode and the non-low grayscale display mode may be set according to actual needs without limitations.

As shown in FIG. 1 and FIG. 2, in some optional embodiments, the second mode may include a first display mode and a second display mode, and the resolution of the display panel in the first display mode may be larger than the resolution of the display panel in the second display mode.

In the first display mode, the first light-emitting device 21 and the second light-emitting device 22 may emit light at the same time.

In the second display mode, the first light-emitting device 21 may not emit light, and the second light-emitting device 22 may emit light.

The display panel provided by the present disclosure may have a first display mode and a second display mode in the second mode, and the resolution of the display panel in the first display mode may be larger than the resolution of the display panel in the second display mode. That is, the first display mode may be a high-resolution display mode, and the second display mode may be a low-resolution display mode, and both the high-resolution display mode and the low-resolution display mode may be the non-low grayscale display mode. In the high-resolution display mode, the second light-emitting device 22 may emit light, and the first light-emitting device 21 may also emit light, such that the display panel may achieve a high-resolution display effect. In the low-resolution display mode, the second light-emitting device 22 may emit light, and the first light-emitting device 21 may not emit light, such that the display panel may achieve a low-resolution display effect, effectively reducing energy consumption.

It should be noted that the boundary between the high-resolution display mode and the low-resolution display mode may be set according to actual needs, and the present disclosure does not make any specific limitation on this.

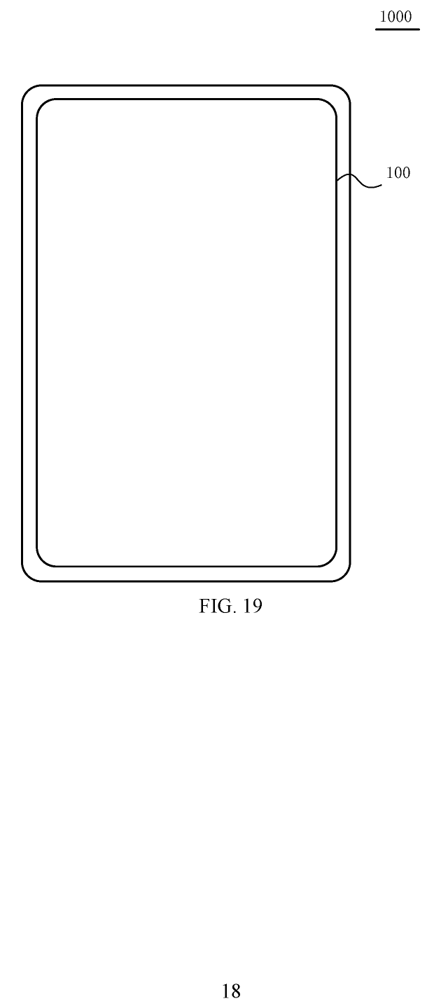

The present disclosure also provides a display device. As shown in FIG. 19, which is a plan view of a display device provided by the present disclosure, in one embodiment, the display device 1000 may include any display panel 100 provided by any of the above embodiments. The embodiment provided in FIG. 19 only takes a mobile phone as an example to illustrate the display device. It can be understood that the display device provided by the embodiments of the present disclosure application may be any electronic product with a display function, including but not limited to the following categories: mobile phones, televisions, laptops, desktop displays, tablet computers, digital cameras, smart bracelets, smart glasses, car displays, medical equipment, industrial control equipment, touch interactive terminals, etc., and the present disclosure does not specifically limit this.

The display device provided by the present disclosure may have the beneficial effects of the display device adopting the above dimming method. For details, references may be made to the specific descriptions of the above embodiments, which will not be repeated here.

In the present disclosure, relational terms such as “first” and “second” are only used to distinguish one entity or operation from another entity or operation, and do not necessarily require or imply that there is a relationship between these entities or operations. There is no such actual relationship or sequence. Furthermore, the terms “comprises”, “include”, or any other variations thereof are intended to cover a non-exclusive inclusion such that a process, method, article, or apparatus that includes a list of elements includes not only those elements, but also those not expressly listed, or elements inherent to the process, method, article or equipment. Without further limitation, an element defined by the statement “comprises a...” does not exclude the presence of additional identical elements in a process, method, article, or apparatus that includes the stated element.

Various embodiments have been described to illustrate the operation principles and exemplary implementations. It should be understood by those skilled in the art that the present disclosure is not limited to the specific embodiments described herein and that various other obvious changes, rearrangements, and substitutions will occur to those skilled in the art without departing from the scope of the disclosure. Thus, while the present disclosure has been described in detail with reference to the above described embodiments, the present disclosure is not limited to the above described embodiments, but may be embodied in other equivalent forms without departing from the scope of the present disclosure, which is determined by the appended claims.

What is claimed is:

1. A display panel, comprising:
a substrate; and
a plurality of light-emitting devices located on one side of the substrate,
wherein:
the plurality of light-emitting devices includes first light-emitting devices and second light-emitting devices;
one first light-emitting device includes a first anode portion and a first cathode portion that are arranged opposite to each other, and a first light-emitting layer located between the first anode portion and the first cathode portion; and
one second light-emitting device includes a second anode portion and a second cathode portion that are arranged opposite to each other, and at least two second light-emitting layers located between the second anode portion and the second cathode portion, wherein: a connecting layer is disposed between two adjacent layers of the at least two second light-emitting layers and a light-emitting color of each of the at least two second light-emitting layers is same in the same second light-emitting device.

2. The display panel according to claim 1, wherein:
the display panel includes a plurality of light-emitting device groups, and each light-emitting device group of the plurality of light-emitting device groups includes one first light-emitting device and at least one second light-emitting device that are adjacently arranged; and
in the same light-emitting device group, the light-emitting color of the first light-emitting device is the same as the light-emitting color of the at least one second light-emitting device.

3. The display panel according to claim 2, wherein:
in the same light-emitting device group, an area of a vertical projection pattern of the first light-emitting device on the base substrate is smaller than or equal to an area of a vertical projection pattern of the at least one second light-emitting device on the substrate.

4. The display panel according to claim 2, wherein:
in the same light-emitting device group, the first light-emitting layer in the first light-emitting device is arranged in the same layer as one of the at least one second light-emitting layer in the at least one second light-emitting device.

5. The display panel according to claim 4, wherein:
in the same light-emitting device group, the first light-emitting layer in the first light-emitting device is connected to one of the at least one second light-emitting layer in the at least one second light-emitting device.

6. The display panel according to claim 2, wherein:
the display panel includes a plurality of light-emitting device units, each of which includes at least two of the plurality of light-emitting device groups arranged along a first direction, wherein light-emitting devices in different light-emitting device groups of one same light-emitting device unit emit different colors.

7. The display panel according to claim 6, wherein:
light-emitting devices in one light-emitting device group are arranged along a second direction, wherein the first direction and the second direction intersect; and
in each light-emitting device group, second light-emitting devices are located on the same side of first light-emitting devices, or, in two adjacent light-emitting device groups along the second direction, second light-emitting devices are located on different sides of first light-emitting devices.

8. The display panel according to claim 2, wherein:
the plurality of light-emitting device groups includes first light-emitting device groups, second light-emitting device groups, and third light-emitting device groups, wherein light-emitting colors of light-emitting devices in the first light-emitting device groups, light-emitting colors of light-emitting devices in the second light-emitting device groups and light-emitting colors of light-emitting devices in the third light-emitting device groups are all different;
the display panel includes first light-emitting device group columns and second light-emitting device group columns arranged alternately and repeatedly along a first direction;
one first light-emitting device group column includes the first light-emitting device group and the second light-emitting device group arranged alternately and repeatedly along a second direction, and one second light-emitting device group column includes a plurality of the third light-emitting device groups arranged along the second direction, wherein the first direction and the second direction intersect; and
the light-emitting devices in one first light-emitting device group and one second light-emitting device group are arranged along the first direction, and the light-emitting devices in one third light-emitting device group are arranged along the first direction or the second direction.

9. The display panel according to claim 6, wherein:
light-emitting devices in one light-emitting device group are arranged along the first direction; and
in each light-emitting device group, second light-emitting devices are located on the same side of first light-emitting devices, or, in two adjacent light-emitting device groups along the first direction, second light-emitting devices are located on different sides of first light-emitting devices.

10. The display panel according to claim 2, wherein:
one light-emitting device group includes a first light-emitting device and a second light-emitting device that are adjacent to each other;
in the same light-emitting device group, the first light-emitting device and the second light-emitting device are arranged along a third direction, wherein: a vertical projection pattern of the first light-emitting device on the base substrate and a vertical projection pattern of the second light-emitting device on the base substrate are symmetrical along a first symmetry axis, the first symmetry axis extends along a fourth direction, and the third direction and the fourth direction intersect.

11. The display panel according to claim 1, further comprising a plurality of partitions, wherein:
at least one partition of the plurality of partitions is provided between two adjacent second light-emitting devices.

12. The display panel according to claim 11, wherein:
one partition is arranged corresponding to one second light-emitting device, and a vertical projection of the partition on the base substrate at least partially surrounds a vertical projection of the corresponding second light-emitting device on the substrate.

13. The display panel according to claim 12, wherein:
a vertical projection pattern of one partition of the plurality of partitions on the base substrate includes notches, and notches of vertical projection patterns of two adjacent partitions on the base substrate are arranged in different orientations.

14. The display panel according to claim 12, wherein:
a vertical projection pattern of one partition of the plurality of partitions on the base substrate includes notches, and notches of vertical projection patterns of two adjacent partitions on the base substrate are not arranged opposite to each other.

15. The display panel according to claim 1, further comprising a plurality of pixel circuits, each of which includes a driving transistor, wherein:
the plurality of pixel circuits includes a first pixel circuit connected to one first light-emitting device, and a second pixel circuit connected to one second light-emitting device, wherein a vertical projection area of a channel of the driving transistor in the first pixel circuit on the base substrate is larger than a vertical projection area of a channel of the driving transistor in the second pixel circuit on the substrate.

16. A driving method of a display panel, comprising:
in a first mode, a brightness of the display panel is L1, first light-emitting devices emit light, and second light-emitting devices do not emit light; and
in a second mode, the brightness of the display panel is L2, the second light-emitting devices emit light, or the first light-emitting devices and the second light-emitting devices emit light at the same time,
wherein:
the display panel includes: a substrate; and a plurality of light-emitting devices located on one side of the substrate;
the plurality of light-emitting devices includes the first light-emitting devices and the second light-emitting devices;
one first light-emitting device includes a first anode portion and a first cathode portion that are arranged opposite to each other, and a first light-emitting layer located between the first anode portion and the first cathode portion; and
one second light-emitting device includes a second anode portion and a second cathode portion that are arranged opposite to each other, and at least two second light-emitting layers located between the second anode portion and the second cathode portion, wherein: a connecting layer is disposed between two adjacent layers of the at least two second light-emitting layers and a light-emitting colors of each of the at least two second light-emitting layers is same in the same second light-emitting device.

17. The method according to claim 16, wherein:
the second mode includes a first display mode and a second display mode, wherein the resolution of the display panel in the first display mode is larger than the resolution of the display panel in the second display mode;
in the first display mode, the first light-emitting devices and the second light-emitting devices emit light simultaneously; and
in the second display mode, the first light-emitting devices do not emit light, and the second light-emitting devices emit light.

18. A display device, comprising a display panel, wherein:
the display panel includes: a substrate; and a plurality of light-emitting devices located on one side of the substrate;
the plurality of light-emitting devices includes first light-emitting devices and second light-emitting devices;
one first light-emitting device includes a first anode portion and a first cathode portion that are arranged opposite to each other, and a first light-emitting layer located between the first anode portion and the first cathode portion; and
one second light-emitting device includes a second anode portion and a second cathode portion that are arranged opposite to each other, and at least two second light-emitting layers located between the second anode portion and the second cathode portion, wherein: a connecting layer is disposed between two adjacent layers of the at least two second light-emitting layers and a light-emitting colors of each of the at least two second light-emitting layers is same in the same second light-emitting device.
